(19) United States
(12) Patent Application Publication
(10) Pub. No.: US 2026/0076062 A1
(43) Pub. Date: Mar. 12, 2026

(54) DISPLAY DEVICE, ELECTRONIC DEVICE, OPTICAL DEVICE, AND METHOD OF MANUFACTURING DISPLAY DEVICE

(71) Applicant: Samsung Display Co., Ltd., Yongin-si (KR)

(72) Inventors: Ye Hwan CHOI, Yongin-si (KR); Jae Been LEE, Yongin-si (KR)

(21) Appl. No.: 19/215,111

(22) Filed: May 21, 2025

(30) Foreign Application Priority Data
Sep. 10, 2024 (KR) 10-2024-0122784

(51) Int. Cl. H10K 59/80; G02B 27/01; H10K 50/19; H10K 59/122

(52) U.S. Cl. CPC H10K 59/80521; G02B 27/0172; H10K 50/19; H10K 59/122; H10K 59/80515; G02B 2027/0178

(57) ABSTRACT

A display device, an optical device and an electronic device each including the display device, and a method of manufacturing a display device are provided. The display device includes: a substrate; a first electrode on the substrate; a pixel defining film on the first electrode and defining an emission area; a light emitting stack on the first electrode; and a second electrode on the light emitting stack and the pixel defining film, wherein a taper angle of the first electrode is less than or equal to about 45 degrees.

### CROSS-REFERENCE TO RELATED APPLICATION

The present application claims priority to and the benefit of Korean Patent Application No. 10-2024-0122784, filed on Sep. 10, 2024, in the Korean Intellectual Property Office, the entire content of which is incorporated herein by reference.

### BACKGROUND

### 1. Field

One or more embodiments of the present disclosure relate to a display device, and, for example, to a display device capable of preventing or reducing a disconnection of a cathode electrode, an optical device, and a method of manufacturing a display device.

### 2. Description of the Related Art

A head mounted display (HMD) is an image display device that is worn on a user's head in the form of glasses or a helmet and forms a focus at a distance close to the user's eyes (in front of the user's eyes). The head mounted display may implement virtual reality (VR) or augmented reality (AR).

The head mounted display magnifies and displays an image displayed on a small display device using a plurality of lenses. Therefore, the display device applied to the head mounted display needs to provide a high-resolution image, for example, an image having a resolution of 3000 pixels per inch (PPI) or more. To this end, an organic light emitting diode on silicon (OLEDoS), which is a small organic light emitting display device with a high resolution, has been used as the display device applied to the head mounted display. The OLEDoS is an image display device in which organic light emitting diodes (OLEDs) are arranged on a semiconductor wafer substrate on which complementary metal oxide semiconductors (CMOSs) circuit is arranged.

### SUMMARY

One or more aspects of embodiments of the present disclosure are directed toward a display device capable of preventing or reducing a disconnection of a cathode electrode, an optical device, and a method of manufacturing a display device. Additional aspects will be set forth in part in the description which follows and, in part, will be apparent from the description, or may be learned by practice of the presented embodiments of the disclosure.

According to one or more embodiments of the present disclosure, a display device includes: a substrate; a first electrode on the substrate; a pixel defining film on (e.g., arranged on) the first electrode and defining an emission area; a light emitting stack on the first electrode; and a second electrode on the light emitting stack and the pixel defining film, wherein a taper angle of the first electrode is smaller (less) than or equal to (e.g., the same as) about 45 degrees.

In addition, according to one or more embodiments of the present disclosure, an optical device includes: a display device; and an optical path changing member on the display device, wherein the display device includes: a substrate; a first electrode on the substrate; a pixel defining film on (e.g., arranged on) the first electrode and defining an emission area; a light emitting stack on the first electrode; and a second electrode on the light emitting stack and the pixel defining film, wherein a taper angle of the first electrode is smaller (less) than or equal to (e.g., the same as) about 45 degrees.

In addition, according to one or more embodiments of the present disclosure, there is provided a method of manufacturing a display device, the method including: placing an insulating film on a substrate; placing a first electrode layer on the insulating film; placing a sacrificial layer on the first electrode layer; placing a first photoresist pattern on the sacrificial layer; forming a sacrificial pattern layer by selectively removing the sacrificial layer using the first photoresist pattern as a mask; and forming a first electrode by selectively removing the first electrode layer using the sacrificial pattern layer as a mask.

In accordance with the display device, the optical device, and the method of manufacturing a display device of one or more embodiments, a taper angle of an anode electrode may be formed to be even. Accordingly, because a step difference of a pixel defining film on the anode electrode may be reduced, a disconnection of a cathode electrode on the pixel defining film may be prevented or reduced. For example, in comparable display devices, the uneven taper angle of the anode electrode often leads to significant step differences in the pixel defining film. This step difference can cause stress and potential disconnection in the cathode electrode, leading to device failure. By ensuring a more even taper angle of the anode electrode, the embodiments of the present disclosure address this issue, thereby enhancing the reliability and longevity of the display device. This improvement is particularly beneficial in high-resolution applications, such as head-mounted displays for virtual reality (VR) and/or augmented reality (AR), where device performance and durability are desirable.

It should be noted that the effects and aspects of the present disclosure may not be limited to embodiments described herein, and the above and other effects and aspects of the disclosure will be apparent from the following description.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects and features of the present disclosure will become more apparent and appreciated from the following descriptions of example embodiments thereof with reference to the accompanying drawings, in which:

FIG. 1 is an exploded perspective view illustrating a display device according to one or more embodiments of the present disclosure;

FIG. 2 is a block diagram illustrating a display device according to one or more embodiments of the present disclosure;

FIG. 3 is an equivalent circuit diagram of a first pixel according to one or more embodiments of the present disclosure;

FIG. 4 is a layout diagram illustrating an example of a display panel according to one or more embodiments of the present disclosure;

FIG. 5 and FIG. 6 are each a layout diagram illustrating an embodiment of the display area of FIG. 4;

FIG. 7 is a cross-sectional view illustrating an example of the display panel taken along the line I1-I1′ of FIG. 5;

FIG. 8 is a cross-sectional view of a display device according to one or more embodiments of the present disclosure;

FIG. 9-20 are cross-sectional views for explaining processes of a method of manufacturing a display device according to one or more embodiments of the present disclosure;

FIG. 21 is a perspective view illustrating a head mounted display device according to one or more embodiments of the present disclosure;

FIG. 22 is an exploded perspective view illustrating an example of the head mounted display device of FIG. 21;

FIG. 23 is a perspective view illustrating a head mounted display device according to one or more embodiments of the present disclosure;

FIG. 24 is a block diagram of an electronic device according to one or more embodiments of the present disclosure; and

FIGS. 25, 26 and 27 are schematic diagrams of electronic devices according to embodiments of the present disclosure.

### DETAILED DESCRIPTION

The present disclosure will now be described more fully hereinafter with reference to the accompanying drawings, in which example embodiments of present disclosure are shown. The disclosure may, however, be embodied in different forms and should not be construed as limited to one or more embodiments set forth herein. Rather, these embodiments are provided so that this disclosure will be thorough and complete, and will fully convey the scope of present disclosure to those skilled in the art.

It will also be understood that if (e.g., when) a layer is referred to as being “on” another layer or substrate, it may be directly on the other layer or substrate, or one or more intervening layers may also be present therebetween. In contrast, “directly on” may refer to that there are no additional intervening elements or layers between the element or layer and the another element or layer. The same or like reference numbers indicate the same or like components throughout the disclosure, and duplicative descriptions thereof may not be provided for conciseness. In the accompanied drawings, the thickness of layers and regions may be exaggerated for clarity.

Although the terms “first”, “second”, and/or the like may be used herein to describe one or more suitable elements, these elements, should not be limited by these terms. These terms may be used to distinguish one element from another element. Thus, a first element discussed may be termed a second element without departing from teachings of one or more embodiments. The description of an element as a “first” element may not require or imply the presence of a second element or other elements. In one or more embodiments, the terms “first”, “second”, and/or the like may also be used herein to differentiate different categories or sets of elements. For conciseness, the terms “first”, “second”, and/or the like may represent “first-category (or first-set)”, “second-category (or second-set)”, and/or the like, respectively.

Features of one or more suitable embodiments of the present disclosure may be combined partially or totally. As will be clearly appreciated by those skilled in the art, technically one or more suitable interactions and operations are possible. Various embodiments may be practiced individually or in combination.

Hereinafter, specific example embodiments will be described in more detail with reference to the accompanying drawings.

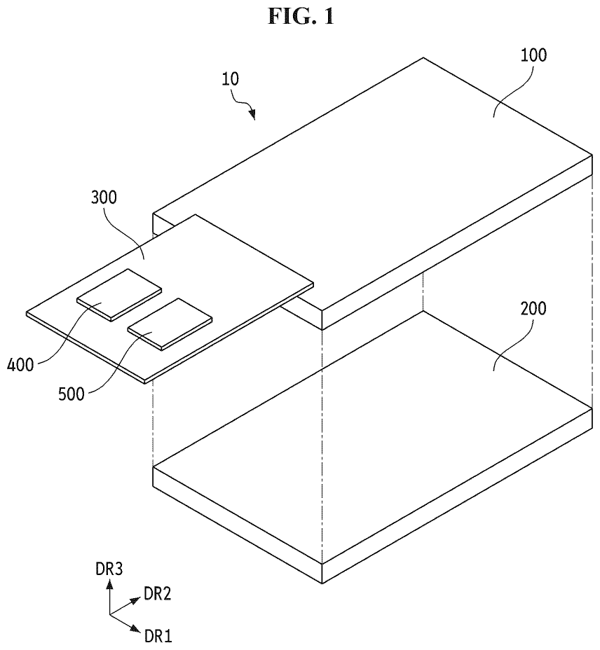

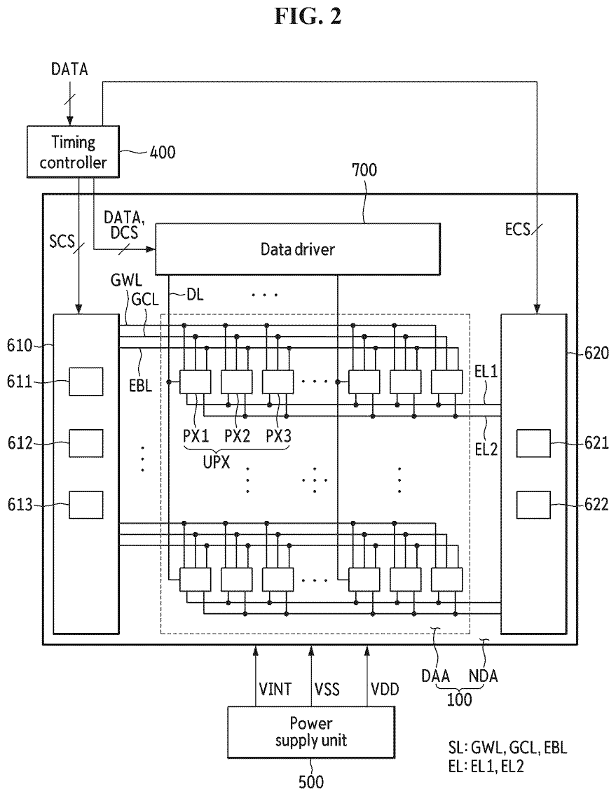

FIG. 1 is an exploded perspective view illustrating a display device according to one or more embodiments of the present disclosure. FIG. 2 is a block diagram illustrating the display device according to one or more embodiments.

Referring to FIG. 1 and FIG. 2, a display device 10 according to one or more embodiments may be a device that displays a moving image or a still image. The display device 10 according to one or more embodiments may be applied to portable electronic devices such as mobile phones, smartphones, tablet personal computers (PCs), mobile communication terminals, electronic notebooks, electronic books, portable multimedia players (PMPs), navigation devices, and/or ultra mobile PCs (UMPCs). For example, the display device 10 according to one or more embodiments may be applied as a display unit of televisions, laptop computers, monitors, billboards, or the Internet of Things (IOTs). In one or more embodiments, the display device 10 may be applied to smart watches, watch phones, or head mounted displays (HMDs) for implementing virtual reality and/or augmented reality.

The display device 10 according to one or more embodiments includes a display panel 100, a heat dissipation layer 200, a circuit board 300, a timing controller 400, and a power supply unit 500.

In one or more embodiments, the display panel 100 may have a shape similar to a rectangular shape in a plan view. For example, in one or more embodiments, the display panel 100 may have a shape similar to a rectangular shape, in a plan view, having short sides in a first direction DR1 and long sides in a second direction DR2 crossing the first direction DR1. In the display panel 100, a corner where the short side in the first direction DR1 and the long side in the second direction DR2 meet may be rounded with a set or predetermined curvature or right-angled. However, the shape of the display panel 100 in a plan view is not limited to the rectangular shape, for example, may be a shape similar to other polygonal shapes, a circular shape, or an elliptical shape. A shape of the display device 10 in a plan view may follow or conform to the shape of the display panel 100 in a plan view, but embodiments of the present disclosure are not limited thereto. Also, in the context of the present disclosure and unless otherwise defined, a plan view is an orthographic projection of a three-dimensional object from the position of a horizontal plane intersecting the object. That is, it is a top-down view, showing the layout and spatial relationships of various elements within the object or structure. A plan view based on a third direction DR3 (e.g., a thickness direction) refers to a top-down view of the object, as if looking directly down onto the surface from above. In this context, the third direction DR3 is perpendicular or normal to the horizontal plane defined by the first direction DR1 and the second direction DR2.

The display panel 100 may include a display area DAA that displays an image and a non-display area NDA that does not display an image, as illustrated in FIG. 2.

The display area DAA includes a plurality of unit pixels UPX, a plurality of scan lines SL, a plurality of emission control lines EL, and a plurality of data lines DL.

The plurality of unit pixels UPX may be arranged in a matrix form in the first direction DR1 and the second direction DR2. The plurality of scan lines SL and the plurality of emission control lines EL may extend in the first direction DR1, while being arranged with one another in the second direction DR2. The plurality of data lines DL may extend in the second direction DR2, while be arranged with one another in the first direction DR1.

The plurality of scan lines SL includes a plurality of write scan lines GWL, a plurality of control scan lines GCL, and a plurality of bias scan lines EBL. The plurality of emission control lines EL include a plurality of first emission control lines EL1 and a plurality of second emission control lines EL2.

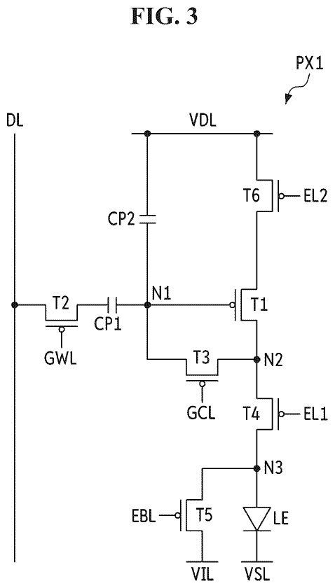

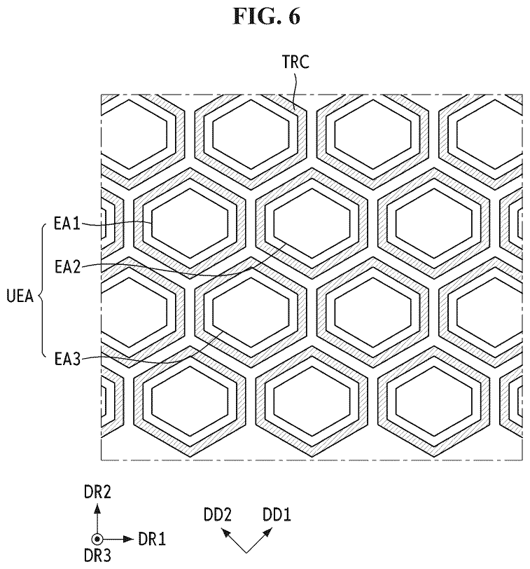

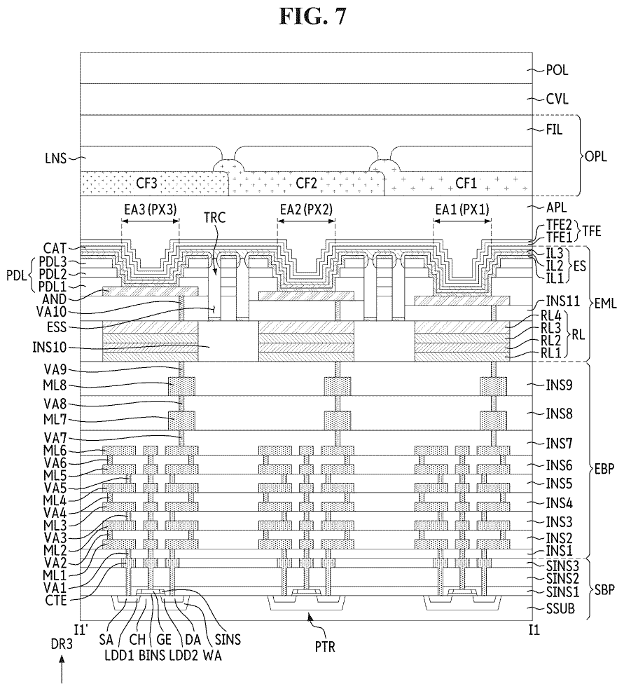

The plurality of unit pixels UPX include a plurality of pixels PX1, PX2, and PX3. Each of the plurality of pixels PX1, PX2, and PX3 may include a plurality of pixel transistors as illustrated in FIG. 3, and the plurality of pixel transistors may be formed by a semiconductor process and be arranged on a semiconductor substrate SSUB (see FIG. 7). For example, in one or more embodiments, a plurality of pixel transistors of a data driver 700 may be formed as complementary metal oxide semiconductors (CMOSs).

Each of the plurality of pixels PX1, PX2, and PX3 may be connected to a (e.g., any one) write scan line GWL selected from among the plurality of write scan lines GWL, a (e.g., any one) control scan line GCL selected from among the plurality of control scan lines GCL, a (e.g., any one) bias scan line EBL selected from among the plurality of bias scan lines EBL, a (e.g., any one) first emission control line EL1 selected from among the plurality of first emission control lines EL1, a (e.g., any one) second emission control line EL2 selected from among the plurality of second emission control lines EL2, and a (e.g., any one) data line DL selected from among the plurality of data lines DL. Each of the plurality of pixels PX1, PX2, and PX3 may receive a data voltage of the data line DL according to a write scan signal of the write scan line GWL, and allow a light emitting element to emit light according to the data voltage.

In one or more embodiments, the non-display area NDA may include a scan driver 610, an emission driver 620, and a data driver 700.

The scan driver 610 includes a plurality of scan transistors, and the emission driver 620 may include a plurality of light emitting transistors. The plurality of scan transistors and the plurality of light emitting transistors may be formed by a semiconductor process and be formed on a semiconductor substrate SSUB (see FIG. 7). For example, in one or more embodiments, the plurality of scan transistors and the plurality of light emitting transistors may be formed as CMOSs. It has been illustrated in FIG. 2 that the scan driver 610 is arranged on the left side of the display area DAA and the emission driver 620 is arranged on the right side of the display area DAA, but embodiments of the present disclosure are not limited thereto. For example, in one or more embodiments, the scan drivers 610 and the emission drivers 620 may be both (e.g., simultaneously) arranged on either the left side or right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines EBL.

The emission driver 620 includes a first emission control driver 621 and a second emission control driver 622. Each of the first emission control driver 621 and the second emission control driver 622 may receive an emission timing control signal ECS from the timing controller 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include a plurality of data transistors, and the plurality of data transistors may be formed by a semiconductor process and be formed on a semiconductor substrate SSUB (see FIG. 7). For example, in one or more embodiments, the plurality of data transistors may be formed as CMOSs.

The data driver 700 may receive digital video data DATA and a data timing control signal DCS from the timing controller 400. The data driver 700 converts the digital video data DATA into analog data voltages according to the data timing control signal DCS and outputs the analog data voltages to the data lines DL. In this regard, the pixels PX1, PX2, and PX3 may be selected by the write scan signals of the scan driver 610, and the data voltages (i.e., analog data voltages) may be supplied to the selected pixels PX1, PX2, and PX3.

The heat dissipation layer 200 may overlap the display panel 100 in the third direction DR3, which is the thickness direction of the display panel 100. The heat dissipation layer 200 may be arranged on a (e.g., one) surface, for example, a rear surface, of the display panel 100. The heat dissipation layer 200 serves to dissipate heat generated from the display panel 100. The heat dissipation layer 200 may include a metal layer made of graphite, silver (Ag), copper (Cu), and/or aluminum (Al), which has high thermal conductivity.

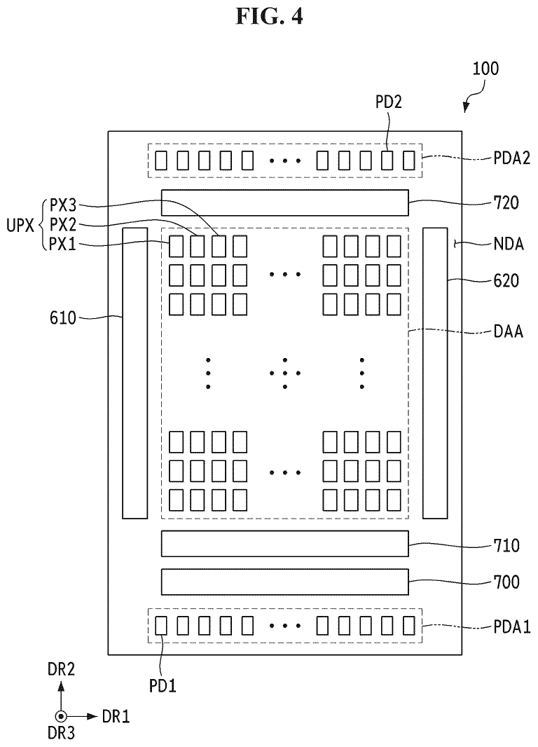

The circuit board 300 may be electrically connected to a plurality of first pads PD1 (see FIG. 4) of a first pad unit PDA1 (see FIG. 4) of the display panel 100 using a conductive adhesive member such as an anisotropic conductive film. In one or more embodiments, the circuit board 300 may be a flexible printed circuit board or a flexible film having a flexible material. It has been illustrated in FIG. 1 that the circuit board 300 is unbent, but, in one or more embodiments, the circuit board 300 may be bent. In these embodiments, one end of the circuit board 300 may be arranged on the rear surface of the display panel 100 and/or a rear surface of the heat dissipation layer 200. The other end of the circuit board 300 that is an end opposite to the one end of the circuit board 300 may be connected to the plurality of first pads PD1 (see FIG. 4) of the first pad unit PDA1 (see FIG. 4) of the display panel 100 using the conductive adhesive member.

The timing controller 400 may receive digital video data and timing signals from the outside. The timing controller 400 may generate the scan timing control signal SCS, the emission timing control signal ECS, and the data timing control signal DCS for controlling the display panel 100 according to the timing signals. The timing controller 400 may output the scan timing control signal SCS to the scan driver 610 and output the emission timing control signal ECS to the emission driver 620. The timing controller 400 may output the digital video data DATA and the data timing control signal DCS to the data driver 700.

The power supply unit 500 may generate a plurality of panel driving voltages according to an external source voltage. For example, in one or more embodiments, the power supply unit 500 may generate a common voltage VSS, a driving voltage VDD, and an initialization voltage VINT and supply the common voltage VSS, the driving voltage VDD, and the initialization voltage VINT to the display panel 100. The common voltage VSS, the driving voltage VDD, and the initialization voltage VINT will be described in more detail later with reference to FIG. 3.

Each of the timing controller 400 and the power supply unit 500 may be formed as an integrated circuit (IC) and attached to one surface of the circuit board 300. In this regard, the scan timing control signal SCS, the emission timing control signal ECS, the digital video data DATA, and the data timing control signal DCS of the timing controller 400 may be supplied to the display panel 100 through the circuit board 300. In addition, the common voltage VSS, the driving voltage VDD, and the initialization voltage VINT of the power supply unit 500 may be supplied to the display panel 100 through the circuit board 300.

In one or more embodiments, each of the timing controller 400 and the power supply unit 500 may be arranged in the non-display area NDA of the display panel 100, similar to the scan driver 610, the emission driver 620, and the data driver 700. In these embodiments, the timing controller 400 may include a plurality of timing transistors, and the power supply unit 500 may include a plurality of power transistors. The plurality of timing transistors and the plurality of power transistors may be formed by a semiconductor process and be formed on a semiconductor substrate SSUB (see FIG. 7). For example, in one or more embodiments, the plurality of timing transistors and the plurality of power transistors may be formed as CMOSs. In one or more embodiments, each of the timing controller 400 and the power supply unit 500 may be arranged between the data driver 700 and the first pad unit PDA1 (see FIG. 4).

FIG. 3 is an equivalent circuit diagram of a first pixel according to one or more embodiments of the present disclosure.

Referring to FIG. 3, a first pixel PX1 may be connected to a write scan line GWL, a control scan line GCL, a bias scan line EBL, a first emission control line EL1, a second emission control line EL2, and a data line DL. In addition, the first pixel PX1 may be connected to a common voltage line VSL to which a common voltage VSS corresponding to a low potential voltage is applied, a driving voltage line VDL to which a driving voltage VDD corresponding to a high potential voltage is applied, and an initialization voltage line VIL to which an initialization voltage VINT is applied. For example, the common voltage line VSL may be a low potential voltage line, the driving voltage line VDL may be a high potential voltage line, and the initialization voltage line VIL may be an initialization voltage line. In this regard, the common voltage VSS may be a voltage lower than the initialization voltage VINT. The driving voltage VDD may be a voltage higher than the initialization voltage VINT.

In one or more embodiments, the first pixel PX1 includes a plurality of transistors T1 to T6, a light emitting element LE, a first capacitor CP1, and a second capacitor CP2.

The light emitting element LE emits light according to a driving current flowing through a channel of a first transistor T1. An amount (e.g., emission intensity) of light emitted from the light emitting element LE may be proportional to the driving current. The light emitting element LE may be arranged between a fourth transistor T4 and the common voltage line VSL. A first electrode of the light emitting element LE may be connected to a drain electrode of the fourth transistor T4, and a second electrode of the light emitting element LE may be connected to the common voltage line VSL. The first electrode of the light emitting element LE may be an anode electrode, and the second electrode of the light emitting element LE may be a cathode electrode. In one or more embodiments, the light emitting element LE may be an organic light emitting diode including a first electrode, a second electrode, and an organic light emitting layer arranged between the first electrode and the second electrode, but embodiments of the present disclosure are not limited thereto. For example, in one or more embodiments, the light emitting element LE may be an inorganic light emitting element including a first electrode, a second electrode, and an inorganic semiconductor arranged between the first electrode and the second electrode, and in these embodiments, the light emitting element LE may be a micro light emitting diode.

The first transistor T1 may be a driving transistor controlling a source-drain current (hereinafter referred to as a “driving current”) flowing between a source electrode and a drain electrode according to a voltage applied to a gate electrode thereof. The first transistor T1 includes the gate electrode connected to a first node N1, the source electrode connected to a drain electrode of a sixth transistor T6, and the drain electrode connected to a second node N2.

A second transistor T2 may be arranged between one electrode of the first capacitor CP1 and the data line DL. The second transistor T2 is turned on by a write scan signal of the write scan line GWL to connect the one electrode of the first capacitor CP1 to the data line DL. For this reason, a data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

A third transistor T3 may be arranged between the first node N1 and the second node N2. The third transistor T3 is turned on by a write control signal of the write control line GCL to connect the first node N1 to the second node N2. For this reason, the gate electrode and the drain electrode of the first transistor T1 are connected to each other, and thus, the first transistor T1 may operate like a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by a first emission control signal of the first emission control line EL1 to connect the second node N2 to the third node N3. For this reason, the driving current of the first transistor T1 may be supplied to the light emitting element LE. The fourth transistor T4 includes a gate electrode connected to the first emission control line EL1, a source electrode connected to the second node N2, and a drain electrode connected to the third node N3.

A fifth transistor T5 may be arranged between the third node N3 and the initialization voltage line VIL. The fifth transistor T5 is turned on by a bias scan signal of the bias scan line EBL to connect the third node N3 to the initialization voltage line VIL. For this reason, the initialization voltage VINT of the initialization voltage line VIL may be applied to the first electrode of the light emitting element LE. The fifth transistor T5 includes a gate electrode connected to the bias scan line EBL, a source electrode connected to the third node N3, and a drain electrode connected to the initialization voltage line VIL.

The sixth transistor T6 may be arranged between the source electrode of the first transistor T1 and the driving voltage line VDL. The sixth transistor T6 is turned on by a second emission control signal of the second emission control line EL2 to connect the source electrode of the first transistor T1 to the driving voltage line VDL. For this reason, the driving voltage VDD of the driving voltage line VDL may be applied to the source electrode of the first transistor T1 . The sixth transistor T6 includes a gate electrode connected to the second emission control line EL2, a source electrode connected to the driving voltage line VDL, and the drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the driving voltage line VDL. The second capacitor CP2 includes one electrode connected to the gate electrode of the first transistor T1 and the other electrode connected to the driving voltage line VDL.

The first node N1 is a contact point between the gate electrode of the first transistor T1, the drain electrode of the third transistor T3, the other electrode of the first capacitor CP1, and the one electrode of the second capacitor CP2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light emitting element LE.

Each of the first to sixth transistors T1 to T6 may be a metal oxide semiconductor field effect transistor (MOSFET). For example, in one or more embodiments, each of the first to sixth transistors T1 to T6 may be a P-type (kind) MOSFET, but embodiments of the present disclosure are not limited thereto. For example, in one or more embodiments, each of the first to sixth transistors T1 to T6 may be an N-type (kind) MOSFET. In one or more embodiments, some of (e.g., selected from among) the first to sixth transistors T1 to T6 may be P-type (kind) MOSFETs, and the others of (e.g., selected from among) the first to sixth transistors T1 to T6 may be N-type (kind) MOSFETs.

It has been illustrated in FIG. 3 that the first pixel PX1 includes six transistors T1 to T6 and two capacitors CP1 and CP2, but the equivalent circuit diagram of the first pixel PX1 is not limited to that illustrated in FIG. 3. For example, the number of transistors and the number of capacitors of the first pixel PX1 are not limited to those illustrated in FIG. 3.

In addition, an equivalent circuit diagram of a second pixel PX2 and an equivalent circuit diagram of a third pixel PX3 may be substantially the same as the equivalent circuit diagram of the first pixel PX1 described with reference to FIG. 3. Therefore, a description of the equivalent circuit diagram of the second pixel PX2 and the equivalent circuit diagram of the third pixel PX3 is not provided in the present disclosure for conciseness.

FIG. 4 is a layout diagram illustrating an example of a display panel according to one or more embodiments of the present disclosure.

Referring to FIG. 4, the display area DAA of the display panel 100 according to one or more embodiments includes a plurality of pixels PX arranged in a matrix form. The non-display area NDA of the display panel 100 according to one or more embodiments includes a scan driver 610, an emission driver 620, a data driver 700, a first distribution circuit 710, a second distribution circuit 720, a first pad unit PDA1, and a second pad unit PDA2.

The scan driver 610 may be arranged on a first side of the display area DAA, and the emission driver 620 may be arranged on a second side of the display area DAA. For example, in one or more embodiments, the scan driver 610 may be arranged on one side of the display area DAA in the first direction DR1, and the emission driver 620 may be arranged on the other side of the display area DAA in the first direction DR1. For example, the scan driver 610 may be arranged on the left side of the display area DAA, and the emission driver 620 may be arranged on the right side of the display area DAA, as illustrated in FIG. 4. However, embodiments of the present disclosure are not limited thereto, for example, the scan drivers 610 and the emission drivers 620 may be arranged on both (e.g., simultaneously) the first and second sides of the display area DAA.

The first pad unit PDA1 may include a plurality of first pads PD1 connected to pads or bumps of the circuit board 300 through a conductive adhesive member. The first pad unit PDA1 may be arranged on a third side of the display area DAA. For example, in one or more embodiments, the first pad unit PDA1 may be arranged on one side of the display area DAA in the second direction DR2.

The first pad unit PDA1 may be arranged outside the data driver 700 in the second direction DR2. For example, the first pad unit PDA1 may be arranged closer to an edge of the display panel 100 than the data driver 700 is.

The second pad unit PDA2 may include a plurality of second pads PD2 corresponding to inspection pads that inspect whether or not the display panel 100 operates normally. The plurality of second pads PD2 may be connected to a jig or a probe pin or connected to a circuit board for inspection in an inspection process. The circuit board for inspection may be a printed circuit board made of a rigid material or a flexible printed circuit board made of a flexible material.

The first distribution circuit 710 distributes data voltages applied through the first pad unit PDA1 to a plurality of data lines DL. For example, in one or more embodiments, the first distribution circuit 710 may distribute data voltages applied through one first pad PD1 of the first pad unit PDA1 to P data lines DL (P is a positive integer of 2 or greater), and for this reason, the number of first pads PD1 may be reduced. The first distribution circuit 710 may be arranged on the third side of the display area DAA of the display panel 100. For example, the first distribution circuit 710 may be arranged on one side of the display area DAA in the second direction DR2. For example, in one or more embodiments, the first distribution circuit 710 may be arranged on a lower side of the display area DAA.

The second distribution circuit 720 distributes signals applied through the second pad unit PDA2 to the scan driver 610, the emission driver 620, and the data lines DL. The second pad unit PDA2 and the second distribution circuit 720 may be components for inspecting an operation of each of the pixels PX of the display area DAA. The second distribution circuit 720 may be arranged on a fourth side of the display area DAA of the display panel 100. For example, the second distribution circuit 720 may be arranged on the other side of the display area DAA in the second direction DR2. For example, in one or more embodiments, the second distribution circuit 720 may be arranged on an upper side of the display area DAA.

In the context of the present disclosure and unless defined otherwise, “one side of the display area DAA in the second direction DR2” refers to a specific side of the display area along the direction labeled as DR2. For instance, if DR2 represents a vertical direction, this may indicate the bottom side of the display area. Conversely, “the other side of the display area DAA in the second direction DR2” refers to the opposite side of the display area along the same direction DR2, which, continuing the previous example, may indicate the top side of the display area. These phrases are used to describe the positioning of components, such as distribution circuits, on opposite sides of the display area along the specified direction DR2.

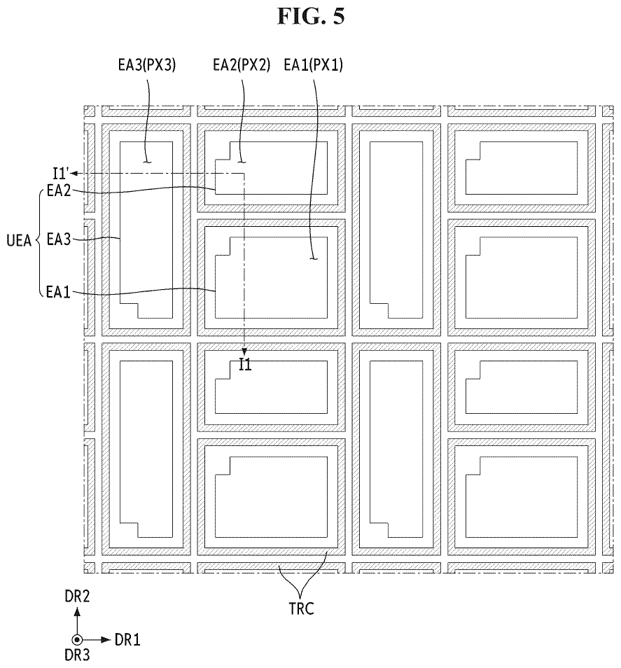

FIG. 5 and FIG. 6 are each a layout diagram illustrating embodiments of the display area of FIG. 4 according to one or more embodiments of the present disclosure.

Referring to FIG. 5 and FIG. 6, each of the plurality of unit pixels UPX includes a first emission area EA1 that is an emission area of the first pixel PX1, a second emission area EA2 that is an emission area of the second pixel PX2, and a third emission area EA3 that is an emission area of the third pixel PX3. For example, in one or more embodiments, the unit pixel UPX may include a unit emission area UEA, and this unit emission area UEA includes the above-described first emission area EA1, second emission area EA2, and third emission area EA3, each of the first emission area EA1, the second emission area EA2, and the third emission area EA3 may be surrounded by a trench TRC. The detailed description of the trench TRC will be described in more detail later with reference to FIG. 7.

Each of the first emission area EA1, the second emission area EA2, and the third emission area EA3 may have a polygonal shape, a circular shape, an elliptical shape, or an irregular shape in a plan view.

In one or more embodiments, a maximum length of the third emission area EA3 in the first direction DR1 may be smaller (less) than a maximum length of the first emission area EA1 in the first direction DR1 and a maximum length of the second emission area EA2 in the first direction DR1. The maximum length of the first emission area EA1 in the first direction DR1 and the maximum length of the second emission area EA2 in the first direction DR1 may be substantially the same as each other.

In one or more embodiments, a maximum length of the third emission area EA3 in the second direction DR2 may be greater than a maximum length of the first emission area EA1 in the second direction DR2 and a maximum length of the second emission area EA2 in the second direction DR2. The maximum length of the first emission area EA1 in the second direction DR2 may be greater than the maximum length of the second emission area EA2 in the second direction DR2. The maximum length of the first emission area EA1 in the second direction DR2 may be smaller (less) than the maximum length of the third emission area EA3 in the second direction DR2.

In one or more embodiments, each of the first emission area EA1, the second emission area EA2, and the third emission area EA3 may have a hexagonal shape including six straight lines, in a plan view, as illustrated in FIG. 5 and FIG. 6, but embodiments of the present disclosure are not limited thereto. For example, each of the first emission area EA1, the second emission area EA2, and the third emission area EA3 may independently have a polygonal shape other than the hexagonal shape, a circular shape, an elliptical shape, or an irregular shape in a plan view.

As illustrated in FIG. 5, in one or more embodiments, in each of the plurality of unit pixels UPX, the first emission area EA1 and the second emission area EA2 may neighbor to each other in the second direction DR2. Additionally, the first emission area EA1 and the third emission area EA3 may neighbor to each other in the first direction DR1. Furthermore, the second emission area EA2 and the third emission area EA3 may neighbor to each other in the first direction DR1. An area of the first emission area EA1, an area of the second emission area EA2, and an area of the third emission area EA3 may be different from one another.

In one or more embodiments, as illustrated in FIG. 6, the first emission area EA1 and the second emission area EA2 may neighbor to each other in the first direction DR1, but the second emission area EA2 and the third emission area EA3 may neighbor to each other in a first diagonal direction DD1, and the first emission area EA1 and the third emission area EA3 may neighbor to each other in a second diagonal direction DD2. The first diagonal direction DD1 is a direction between the first direction DR1 and the second direction DR2 and may refer to a direction inclined by 45° with respect to the first direction DR1 and the second direction DR2, and the second diagonal direction DD2 may be a direction orthogonal to the first diagonal direction DD1.

For example, as illustrated in FIG. 5, in one or more embodiments, each of the plurality of unit pixels UPX includes the first emission area EA1 and the second emission area EA2 that may be adjacent to each other in the second direction DR2. Additionally, the first emission area EA1 and the third emission area EA3 may be adjacent to each other in the first direction DR1, and the second emission area EA2 and the third emission area EA3 may be adjacent to each other in the first direction DR1. The areas of the first emission area EA1, the second emission area EA2, and the third emission area EA3 may differ from one another. Alternatively, as illustrated in FIG. 6, the first emission area EA1 and the second emission area EA2 may be adjacent to each other in the first direction DR1, while the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 is a direction between the first direction DR1 and the second direction DR2, inclined by 45° with respect to both, and the second diagonal direction DD2 is orthogonal to the first diagonal direction DD1.

The first emission area EA1 may be to emit light of a first color, the second emission area EA2 may be to emit light of a second color, and the third emission area EA3 may be to emit light of a third color. In one or more embodiments, the light of the first color may be light of a blue wavelength band, the light of the second color may be light of a green wavelength band, and the light of the third color may be light of a red wavelength band. For example, the blue wavelength band may indicate that a main peak wavelength of the light is in a wavelength band of approximately (about) 370 nanometers (nm) to about 460 nm, the green wavelength band may indicate that a main peak wavelength of the light is in a wavelength band of approximately (about) 480 nm to about 560 nm, and the red wavelength band may indicate that a main peak wavelength of the light is in a wavelength band of approximately (about) 600 nm and about 750 nm.

It has been illustrated in FIG. 5 and FIG. 6 that each of the plurality of unit pixels UPX includes three emission areas EA1, EA2, and EA3, but embodiments of the present disclosure are not limited thereto. For example, in one or more embodiments, each of the plurality of unit pixels UPX may include four emission areas.

In addition, an arrangement of the emission areas of the plurality of unit pixels UPX is not limited to those illustrated in FIG. 5 and FIG. 6. For example, in one or more embodiments, the emission areas of the plurality of unit pixels UPX may be arranged in a stripe structure in which the emission areas are arranged in the first direction DR1, a PenTile® structure in which the emission areas have a diamond arrangement, or a hexagonal structure in which emission areas having a hexagonal shape in a plan view are arranged as illustrated in FIG. 6. PenTile® is a duly registered trademark of Samsung Display Co., Ltd.

FIG. 7 is a cross-sectional view illustrating an example of the display panel taken along the line I1-I1′ of FIG. 5.

Referring to FIG. 7, the display panel 100 includes a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may include (e.g., be) the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with first-type (kind) impurities. A plurality of well regions WA may be arranged in an upper surface of the semiconductor substrate SSUB. The plurality of well regions WA may be regions doped with second-type (kind) impurities. The second-type (kind) impurities may be different from the aforementioned first-type (kind) impurities. For example, in one or more embodiments, if (e.g., when) the first-type (kind) impurities are p-type (kind) impurities, the second-type (kind) impurities may be n-type (kind) impurities. In one or more embodiments, if (e.g., when) the first-type (kind) impurities are n-type (kind) impurities, the second-type (kind) impurities may be p-type (kind) impurities.

Each of the plurality of well regions WA includes a source region SA corresponding to a source electrode of the pixel transistor PTR, a drain region DA corresponding to a drain electrode of the pixel transistor PTR, and a channel region CH arranged between the source region SA and the drain region DA.

A bottom insulating film BINS may be arranged between a gate electrode GE and the well region WA. Side surface insulating films SINS may be arranged on side surfaces of the gate electrode GE. The side surface insulating films SINS may be arranged on the bottom insulating film BINS.

Each of the source region SA and the drain region DA may be a region doped with the first-type (kind) impurities. The gate electrode GE of the pixel transistor PTR may overlap the well region WA in the third direction DR3. The channel region CH may overlap the gate electrode GE in the third direction DR3. The source region SA may be arranged on one side of the gate electrode GE, and the drain region DA may be arranged on the other side of the gate electrode GE.

Each of the plurality of well regions WA may further include a first low-concentration impurity region LDD1 arranged between the channel region CH and the source region SA and a second low-concentration impurity region LDD2 arranged between the channel region CH and the drain region DA. The first low-concentration impurity region LDD1 may be a region having a lower impurity concentration than the source region SA due to the bottom insulating film BINS. The second low-concentration impurity region LDD2 may be a region having a lower impurity concentration than the drain region DA due to the bottom insulating film BINS. A distance between the source region SA and the drain region DA may increase due to the first low-concentration impurity region LDD1 and the second low-concentration impurity region LDD2. Therefore, a length of the channel region CH of each of the pixel transistors PTR may increase, and thus, punch-through and hot carrier phenomena caused by a short channel may be prevented or reduced.

A first semiconductor insulating film SINS1 may be arranged on the semiconductor substrate SSUB. In one or more embodiments, the first semiconductor insulating film SINS1 may be formed as a silicon carbonitride (SiCN) and/or silicon oxide (SiOₓ)-based inorganic film, but embodiments of the present disclosure are not limited thereto.

A second semiconductor insulating film SINS2 may be arranged on the first semiconductor insulating film SINS1. In one or more embodiments, the second semiconductor insulating film SINS2 may be formed as a silicon oxide (SiOₓ)-based inorganic film, but embodiments of the present disclosure are not limited thereto.

The plurality of contact terminals CTE may be arranged on the second semiconductor insulating film SINS2. Each of the plurality of contact terminals CTE may be connected to any one of the gate electrode GE, the source region SA, and the drain region DA of each of the pixel transistors PTR through a hole penetrating through the first semiconductor insulating film SINS1 and the second semiconductor insulating film SINS2. Each of the plurality of contact terminals CTE may be made of any one selected from among copper (Cu), aluminum (Al), tungsten (W), molybdenum (Mo), chromium (Cr), gold (Au), titanium (Ti), nickel (Ni), and neodymium (Nd), or an alloy or a compound thereof.

A third semiconductor insulating film SINS3 may be arranged on side surfaces of each of the plurality of contact terminals CTE. An upper surface of each of the plurality of contact terminals CTE may be exposed without being covered by the third semiconductor insulating film SINS3. In one or more embodiments, the third semiconductor insulating film SINS3 may be formed as a silicon oxide (SiOₓ)-based inorganic film, but embodiments of the present disclosure are not limited thereto.

In one or more embodiments, the semiconductor substrate SSUB may be replaced with a glass substrate or a polymer resin substrate such as a polyimide substrate. In these embodiments, thin film transistors may be arranged on the glass substrate or the polymer resin substrate. The glass substrate may be a rigid substrate that is not bent, and the polymer resin substrate may be a flexible substrate that may be bent or curved.

The light emitting element backplane EBP includes a plurality of conductive layers ML1 to ML8, a plurality of vias VA1 to VA9, and a plurality of insulating films INS1 to INS9. In one or more embodiments, the light emitting element backplane EBP includes a plurality of insulating films INS1 to INS9 arranged between first to eighth conductive layers ML1 to ML8.

The first to eighth conductive layers ML1 to ML8 serve to implement a circuit of the first pixel PX1 illustrated in FIG. 3 by connecting the plurality of contact terminals CTE exposed from the semiconductor backplane SBP to one another. For example, in one or more embodiments, only the first to sixth transistors T1 to T6 are formed in the semiconductor backplane SBP, and the connection between the first to sixth transistors T1 to T6 and the formation of the first capacitor CP1 and the second capacitor CP2 are performed and accomplished through the first to eighth conductive layers ML1 to ML8. In addition, the connection between a drain region corresponding to the drain electrode of the fourth transistor T4, a source region corresponding to the source electrode of the fifth transistor T5, and the first electrode of the light emitting element LE is also performed and accomplished through the first to eighth conductive layers ML1 to ML8.

A first insulating film INS1 may be arranged on the semiconductor backplane SBP. Each of first vias VA1 may penetrate through the first insulating film INS1 to be connected to the contact terminal CTE exposed from the semiconductor backplane SBP. Each of the first conductive layers ML1 may be arranged on the first insulating film INS1 and be connected to the first via VA1.

A second insulating film INS2 may be arranged on the first insulating film INS1 and the first conductive layers ML1. Each of second vias VA2 may penetrate through the second insulating film INS2 to be connected to the exposed first conductive layer ML1. Each of the second conductive layers ML2 may be arranged on the second insulating film INS2 and be connected to the second via VA2.

A third insulating film INS3 may be arranged on the second insulating film INS2 and the second conductive layers ML2. Each of third vias VA3 may penetrate through the third insulating film INS3 to be connected to the exposed second conductive layer ML2. Each of the third conductive layers ML3 may be arranged on the third insulating film INS3 and be connected to the third via VA3.

A fourth insulating film INS4 may be arranged on the third insulating film INS3 and the third conductive layers ML3. Each of fourth vias VA4 may penetrate through the fourth insulating film INS4 to be connected to the exposed third conductive layer ML3. Each of the fourth conductive layers ML4 may be arranged on the fourth insulating film INS4 and be connected to the fourth via VA4.

A fifth insulating film INS5 may be arranged on the fourth insulating film INS4 and the fourth conductive layers ML4. Each of fifth vias VA5 may penetrate through the fifth insulating film INS5 to be connected to the exposed fourth conductive layer ML4. Each of the fifth conductive layers ML5 may be arranged on the fifth insulating film INS5 and be connected to the fifth via VA5.

A sixth insulating film INS6 may be arranged on the fifth insulating film INS5 and the fifth conductive layers ML5. Each of sixth vias VA6 may penetrate through the sixth insulating film INS6 to be connected to the exposed fifth conductive layer ML5.

Each of the sixth conductive layers ML6 may be arranged on the sixth insulating film INS6 and be connected to the sixth via VA6.

A seventh insulating film INS7 may be arranged on the sixth insulating film INS6 and the sixth conductive layers ML6. Each of seventh vias VA7 may penetrate through the seventh insulating film INS7 to be connected to the exposed sixth conductive layer ML6. Each of the seventh conductive layers ML7 may be arranged on the seventh insulating film INS7 and be connected to the seventh via VA7.

An eighth insulating film INS8 may be arranged on the seventh insulating film INS7 and the seventh conductive layers ML7. Each of eighth vias VA8 may penetrate through the eighth insulating film INS8 to be connected to the exposed seventh conductive layer ML7. Each of the eighth conductive layers ML8 may be arranged on the eighth insulating film INS8 and be connected to the eighth via VA8.

The first to eighth conductive layers ML1 to ML8 and the first to eighth vias VA1 to VA8 may be made of substantially the same material. In one or more embodiments, each of the first to eighth conductive layers ML1 to ML8 and the first to eighth vias VA1 to VA8 may be made of any one selected from among copper (Cu), aluminum (Al), tungsten (W), molybdenum (Mo), chromium (Cr), gold (Au), titanium (Ti), nickel (Ni), and neodymium (Nd), or an alloy or a compound thereof. The first to eighth vias VA1 to VA8 may be made of substantially the same material. The first to eighth insulating films INS1 to INS8 may each be formed as a silicon oxide (SiOₓ)-based inorganic film, but embodiments of the present disclosure are not limited thereto.

A thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than a thickness of the first via VA1, a thickness of the second via VA2, a thickness of the third via VA3, a thickness of the fourth via VA4, a thickness of the fifth via VA5, and a thickness of the sixth via VA6, respectively. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same as one another. For example, in one or more embodiments, the thickness of the first conductive layer ML1 may be approximately (about) 1360 Angstroms (Å) (i.e., 10⁻¹⁰ m), each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be approximately (about) 1440 Å, and each of the thickness of the first via VA1, the thickness of the second via VA2, the thickness of the third via VA3, the thickness of the fourth via VA4, the thickness of the fifth via VA5, and the thickness of the sixth via VA6 may be approximately (about) 1150 Å.

Each of a thickness of the seventh conductive layer ML7 and a thickness of the eighth conductive layer ML8 may be greater than each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the eighth conductive layer ML8 may be greater than a thickness of the seventh via VA7 and a thickness of the eighth via VA8, respectively. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same as each other. For example, in one or more embodiments, each of the thickness of the seventh conductive layer ML7 and the thickness of the eighth conductive layer ML8 may be approximately (about) 9000 Å. Each of the thickness of the seventh via VA7 and the thickness of the eighth via VA8 may be approximately (about) 6000 Å.

A ninth insulating film INS9 may be arranged on the eighth insulating film INS8 and the eighth conductive layer ML8. In one or more embodiments, the ninth insulating film INS9 may be formed as a silicon oxide (SiOₓ)-based inorganic film, but embodiments of the present disclosure are not limited thereto.

Each of ninth vias VA9 may penetrate through the ninth insulating film INS9 to be connected to the exposed eighth conductive layer ML8. Each of the ninth vias VA9 may be made of any one selected from among copper (Cu), aluminum (Al), tungsten (W), molybdenum (Mo), chromium (Cr), gold (Au), titanium (Ti), nickel (Ni), and neodymium (Nd), or an alloy or a compound thereof. In one or more embodiments, a thickness of the ninth via VA9 may be approximately (about) 16500 Å.

The display element layer EML may be arranged on the light emitting element backplane EBP. The display element layer EML may include a reflective electrode layer RL, tenth and eleventh insulating films INS10 and INS11, tenth vias VA10, light emitting elements LE each including a first electrode AND, a light emitting stack ES, and a second electrode CAT, a pixel defining film PDL, and a plurality of trenches TRC.

The reflective electrode layer RL may be arranged on the ninth insulating film INS9. The reflective electrode layer RL may include one or more selected from among reflective electrodes RL1, RL2, RL3, and RL4. For example, in one or more embodiments, the reflective electrode layer RL may include first to fourth reflective electrodes RL1, RL2, RL3, and RL4 as illustrated in FIG. 7.

Each of the first reflective electrodes RL1 may be arranged on the ninth insulating film INS9 and be connected to the ninth via VA9. Each of the first reflective electrodes RL1 may be made of any one selected from among copper (Cu), aluminum (Al), tungsten (W), molybdenum (Mo), chromium (Cr), gold (Au), titanium (Ti), nickel (Ni), and neodymium (Nd), or an alloy or a compound thereof. For example, in one or more embodiments, each of the first reflective electrodes RL1 may include titanium nitride (TiN).

Each of the second reflective electrodes RL2 may be arranged on the first reflective electrode RL1. Each of the second reflective electrodes RL2 may be made of any one selected from among copper (Cu), aluminum (Al), tungsten (W), molybdenum (Mo), chromium (Cr), gold (Au), titanium (Ti), nickel (Ni), and neodymium (Nd), or an alloy or a compound thereof. For example, in one or more embodiments, each of the second reflective electrodes RL2 may include aluminum (Al).

Each of the third reflective electrodes RL3 may be arranged on the second reflective electrode RL2. Each of the third reflective electrodes RL3 may be made of any one selected from among copper (Cu), aluminum (Al), tungsten (W), molybdenum (Mo), chromium (Cr), gold (Au), titanium (Ti), nickel (Ni), and neodymium (Nd), or an alloy or a compound thereof. For example, in one or more embodiments, each of the third reflective electrodes RL3 may include titanium nitride (TiN).

Each of the fourth reflective electrodes RL4 may be arranged on the third reflective electrode RL3. Each of the fourth reflective electrodes RL4 may be made of any one selected from among copper (Cu), aluminum (Al), tungsten (W), molybdenum (Mo), chromium (Cr), gold (Au), titanium (Ti), nickel (Ni), and neodymium (Nd), or an alloy or a compound thereof. For example, in one or more embodiments, each of the fourth reflective electrodes RL4 may include titanium (Ti).

Because the second reflective electrodes RL2 are electrodes substantially reflecting light from the light emitting elements LE, a thickness of the second reflective electrode RL2 may be greater than a thickness of the first reflective electrode RL1, a thickness of the third reflective electrode RL3, and a thickness of the fourth reflective electrode RL4. For example, in one or more embodiments, the thickness of the first reflective electrode RL1, the third reflective electrode RL3, and the fourth reflective electrode RL4 may be approximately (about) 100 Å, and the thickness of the second reflective electrode RL2 may be approximately (about) 850 Å.

The tenth insulating film INS10 may be arranged on the ninth insulating film INS9. The tenth insulating film INS10 may be arranged between the reflective electrode layers RL adjacent to each other in a horizontal direction. In one or more embodiments, the tenth insulating film INS10 may be arranged on the reflective electrode layer RL in the third pixel PX3. In one or more embodiments, the tenth insulating film INS10 may be formed as a silicon oxide (SiOₓ)-based inorganic film, but embodiments of the present disclosure are not limited thereto.

The eleventh insulating film INS11 may be arranged on the tenth insulating film INS10 and the reflective electrode layer RL. In one or more embodiments, the eleventh insulating film INS11 may be formed as a silicon oxide (SiOₓ)-based inorganic film, but embodiments of the present disclosure are not limited thereto. The tenth insulating film INS10 and the eleventh insulating film INS11 may be optical auxiliary layers through which light reflected by the reflective electrode layer RL among light emitted from the light emitting elements LE passes.

In order to adjust a resonance distance of the light emitted from the light emitting elements LE in at least one of the first pixel PX1, the second pixel PX2, or the third pixel PX3, in one or more embodiments, the tenth insulating film INS10 and the eleventh insulating film INS11 may not be provided and arranged below the first electrode AND of the first pixel PX1. The first electrode AND of the first pixel PX1 may be directly arranged on the reflective electrode layer RL. The eleventh insulating film INS11 may be arranged below the first electrode AND of the second pixel PX2. The tenth insulating film INS10 and the eleventh insulating film INS11 may be arranged below the first electrode AND of the third pixel PX3.

In summary, a distance between the first electrode AND and the reflective electrode layer RL may be different in each of the first pixel PX1, the second pixel PX2, and the third pixel PX3. For example, in order to adjust a distance from the reflective electrode layer RL to the second electrode CAT according to a main wavelength of light emitted from each of the first pixel PX1, the second pixel PX2, and third pixel PX3, the presence or absence of the tenth insulating film INS10 and the eleventh insulating film INS11 may be set in each of the first pixel PX1, the second pixel PX2, and the third pixel PX3. For example, it has been illustrated in FIG. 7 that a distance between the first electrode AND and the reflective electrode layer RL in the third pixel PX3 is greater than a distance between the first electrode AND and the reflective electrode layer RL in the second pixel PX2 and a distance between the first electrode AND and the reflective electrode layer RL in the first pixel PX1, and the distance between the first electrode AND and the reflective electrode layer RL in the second pixel PX2 is greater than the distance between the first electrode AND and the reflective electrode layer RL in the first pixel PX1, but embodiments of the present disclosure are not limited thereto.

In addition, the tenth insulating film INS10 and the eleventh insulating film INS11 have been illustrated in one or more embodiments of the present disclosure, but, in one or more embodiments, a twelfth insulating film arranged below the first electrode AND of the first pixel PX1 may be added. In these embodiments, the eleventh insulating film INS11 and a twelfth insulating film may be arranged below the first electrode AND of the second pixel PX2, and the tenth insulating film INS10, the eleventh insulating film INS11, and the twelfth insulating film may be arranged below the first electrode AND of the third pixel PX3.

Each of the tenth vias VA10 may penetrate through the tenth insulating film INS10 and/or the eleventh insulating film INS11 in the first pixel PX1, the second pixel PX2, and the third pixel PX3 to be connected to the exposed fourth reflective electrode RL4. Each of the tenth vias VA10 may be made of any one selected from among copper (Cu), aluminum (Al), tungsten (W), molybdenum (Mo), chromium (Cr), gold (Au), titanium (Ti), nickel (Ni), and neodymium (Nd), or alloys thereof. A thickness of the tenth via VA10 in the second pixel PX2 may be smaller (less) than a thickness of the tenth via VA10 in the third pixel PX3. A thickness of the tenth via VA10 in the first pixel PX1, if present in the first pixel PX1, may be smaller (less) than the thickness of the tenth via VA10 in the second pixel PX2.

The first electrode AND of each of the light emitting elements LE may be arranged on the tenth insulating film INS10 and be connected to the tenth via VA10. The first electrode AND of each of the light emitting elements LE may be connected to the drain region DA or the source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be made of any one selected from among copper (Cu), aluminum (Al), tungsten (W), molybdenum (Mo), chromium (Cr), gold (Au), titanium (Ti), nickel (Ni), and neodymium (Nd), or an alloy or a compound thereof. For example, in one or more embodiments, the first electrode AND of each of the light emitting elements LE may be made of titanium nitride (TiN).

The pixel defining film PDL may be arranged on a partial area of the first electrode AND of each of the light emitting elements LE. The pixel defining film PDL may cover an edge of the first electrode AND of each of the light emitting elements LE. The pixel defining film PDL serves to partition the first emission areas EA1, the second emission areas EA2, and the third emission areas EA3.

The first emission area EA1 may be defined as an area where the first electrode AND, the light emitting stack ES, and the second electrode CAT are sequentially stacked in the first pixel PX1 to emit light. The second emission area EA2 may be defined as an area where the first electrode AND, the light emitting stack ES, and the second electrode CAT are sequentially stacked in the second pixel PX2 to emit light. The third emission area EA3 may be defined as an area where the first electrode AND, the light emitting stack ES, and the second electrode CAT are sequentially stacked in the third pixel PX3 to emit light.

The pixel defining film PDL may include first to third pixel defining films PDL1, PDL2, and PDL3. The first pixel defining film PDL1 may be arranged on the edge of the first electrode AND of each of the light emitting elements LE, the second pixel defining film PDL2 may be arranged on the first pixel defining film PDL1, and the third pixel defining film PDL3 may be arranged on the second pixel defining film PDL2. In one or more embodiments, the first pixel defining film PDL1, the second pixel defining film PDL2, and the third pixel defining film PDL3 may each be formed as a silicon oxide (SiOₓ)-based inorganic film, but embodiments of the present disclosure are not limited thereto. Each of a thickness of the first pixel defining film PDL1, a thickness of the second pixel defining film PDL2, and a thickness of the third pixel defining film PDL3 may be approximately (about) 500 Å.

When the first pixel defining film PDL1, the second pixel defining film PDL2, and the third pixel defining film PDL3 are formed as one pixel defining film, a height of the one pixel defining film increases, such that a first encapsulation inorganic film TFE1 may be disconnected due to step coverage. The step coverage refers to a ratio of a degree at which a thin film is coated on an inclined portion to a degree at which a thin film is coated on a flat portion. The lower the step coverage, the more likely it is that the thin film will be disconnected at the inclined portion.

Therefore, in order to prevent or reduce the first encapsulation inorganic film TFE1 from being disconnected due to the step coverage, the first pixel defining film PDL1, the second pixel defining film PDL2, and the third pixel defining film PDL3 may have a cross-sectional structure with a step having a staircase shape. For example, in one or more embodiments, a width of the first pixel defining film PDL1 may be greater than a width of the second pixel defining film PDL2 and a width of the third pixel defining film PDL3, and the width of the second pixel defining film PDL2 may be greater than the width of the third pixel defining film PDL3. The width of the first pixel defining film PDL1 refers to a length, in the horizontal direction, of the first pixel defining film PDL1 defined by the first direction DR1 and the second direction DR2.

Each of the plurality of trenches TRC may penetrate through the first pixel defining film PDL1, the second pixel defining film PDL2, and the third pixel defining film PDL3. In addition, each of the plurality of trenches TRC may penetrate through the eleventh insulating film INS11. In one or more embodiments, in each of the plurality of trenches TRC, the tenth insulating film INS10 may have a shape in which a portion thereof is trenched.

At least one trench TRC may be arranged between the pixels PX1, PX2, and PX3 neighboring to one another (e.g., between neighboring pixels PX1, PX2, and PX3). It has been illustrated in FIG. 7 that two trenches TRC are arranged between the pixels PX1, PX2, and PX3 neighboring to one another, but embodiments of the present disclosure are not limited thereto.

The light emitting stack ES may include a plurality of stack layers. It has been illustrated in FIG. 7 that the light emitting stack ES has a three-tandem structure including a first stack layer IL1, a second stack layer IL2, and a third stack layer IL3, but embodiments of the present disclosure are not limited thereto. For example, in one or more embodiments, the light emitting stack ES may have a two-tandem structure including two stack layers.

In the three-tandem structure, the light emitting stack ES may have a tandem structure including a plurality of stack layers IL1, IL2, and IL3 emitting different light.

For example, in one or more embodiments, the light emitting stack ES may include a first stack layer IL1 emitting light of the first color, a second stack layer IL2 emitting light of the third color, and a third stack layer IL3 emitting light of the second color. The first stack layer IL1, the second stack layer IL2, and the third stack layer IL3 may be sequentially stacked.

The first stack layer IL1 may have a structure in which a first hole transporting layer, a first organic light emitting layer emitting the light of the first color, and a first electron transporting layer are sequentially stacked. The second stack layer IL2 may have a structure in which a second hole transporting layer, a second organic light emitting layer emitting the light of the third color, and a second electron transporting layer are sequentially stacked. The third stack layer IL3 may have a structure in which a third hole transporting layer, a third organic light emitting layer emitting the light of the second color, and a third electron transporting layer are sequentially stacked.

In one or more embodiments, a first charge generation layer for supplying charges to the second stack layer IL2 and supplying electrons to the first stack layer IL1 may be arranged between the first stack layer IL1 and the second stack layer IL2. The first charge generation layer may include an N-type (kind) charge generation layer supplying electrons to the first stack layer IL1 and a P-type (kind) charge generation layer supplying holes to the second stack layer IL2. The N-type (kind) charge generation layer may include a dopant of a metal material.

A second charge generation layer for supplying charges to the third stack layer IL3 and supplying electrons to the second stack layer IL2 may be arranged between the second stack layer IL2 and the third stack layer IL3. The second charge generation layer may include an N-type (kind) charge generation layer supplying electrons to the second stack layer IL2 and a P-type (kind) charge generation layer supplying holes to the third stack layer IL3.

The first stack layer IL1 may be arranged on the first electrodes AND and the pixel defining film PDL, and may be arranged on a bottom surface of each of the trenches TRC. Due to the trenches TRC, the first stack layer IL1 may be disconnected between the pixels PX1, PX2, and PX3 neighboring to one another (e.g., between neighboring pixels PX1, PX2, and PX3). The second stack layer IL2 may be arranged on the first stack layer IL1. Due to the trenches TRC, the second stack layer IL2 may be disconnected between the pixels PX1, PX2, and PX3 neighboring to one another. A cavity ESS or an empty space may be arranged between the first stack layer IL1 and the second stack layer IL2 in each of the trenches TRC. The third stack layer IL3 may be arranged on the second stack layer IL2. The third stack layer IL3 may not be disconnected by the trenches TRC, and may be arranged to cover the second stack layer IL2 in each of the trenches TRC. For example, in one or more embodiments, in the three-tandem structure, each of the plurality of trenches TRC may be a structure for disconnecting the first and second stack layers IL1 and IL2, the first charge generation layer, and the second charge generation layer of the display element layer EML between the pixels PX1, PX2, and PX3 neighboring to one another. In addition, in the two-tandem structure, each of the plurality of trenches TRC may be a structure for disconnecting a lower intermediate layer and a charge generation layer arranged between the lower intermediate layer and an upper intermediate layer.

In order to stably disconnect the first and second stack layers IL1 and IL2 of the display element layer EML between the pixels PX1, PX2, and PX3 neighboring to one another, a height of each of the plurality of trenches TRC may be greater than a height of the pixel defining film PDL. The height of each of the plurality of trenches TRC refers to a length of each of the plurality of trenches TRC in the third direction DR3. The height of the pixel defining film PDL refers to a length of the pixel defining film PDL in the third direction DR3. In order to disconnect the first and second intermediate layers IL1 and IL2 of the display element layer EML between the pixels PX1, PX2, and PX3 neighboring to one another, other structures may exist instead of the trenches TRC. For example, in one or more embodiments, instead of the trenches TRC, partition walls having a reverse tapered shape may be arranged on the pixel defining film PDL.

The number of stack layers IL1, IL2, and IL3 each emitting the different light is not limited to that illustrated in FIG. 7. For example, in one or more embodiments, the light emitting stack ES may include two intermediate layers. In these embodiments, any one of (e.g., selected from among) the two intermediate layers may be substantially the same as the first stack layer IL1, and the other of (e.g., selected from among) the two intermediate layers may include a second hole transporting layer, a second organic light emitting layer, a third organic light emitting layer, and a second electron transporting layer. In these embodiments, a charge generation layer for supplying electrons to any one intermediate layer and supplying charges to the other intermediate layer may be arranged between the two intermediate layers.

It has been illustrated in FIG. 7 that the first to third stack layers IL1, IL2, and IL3 are all arranged in the first emission area EA1, the second emission area EA2, and the third emission area EA3, but embodiments of the present disclosure are not limited thereto. For example, in one or more embodiments, the first stack layer IL1 may be arranged in the first emission area EA1, and may not be provided and arranged in the second emission area EA2 and the third emission area EA3. In addition, the second stack layer IL2 may be arranged in the second emission area EA2, and may not be provided and arranged in the first emission area EA1 and the third emission area EA3. In addition, the third stack layer IL3 may be arranged in the third emission area EA3, and may not be provided and arranged in the first emission area EA1 and the second emission area EA2. In these embodiments, first to third color filters CF1, CF2, and CF3 of the optical layer OPL may not be provided.

The second electrode CAT may be arranged on the third stack layer IL3. The second electrode CAT may be arranged on the third stack layer IL3 in each of the plurality of trenches TRC. The second electrode CAT may be made of a transparent conductive material (TCO) such as indium tin oxide (ITO) or indium zinc oxide (IZO) capable of transmitting light therethrough or a semi-transmissive conductive material such as magnesium (Mg), silver (Ag), or an alloy of magnesium (Mg) and silver (Ag). When the second electrode CAT is made of the semi-transmissive conductive material, light emission efficiency of each of the first to third pixels PX1, PX2, and PX3 may be increased by a micro cavity.

The encapsulation layer TFE may be arranged on the display element layer EML. The encapsulation layer TFE may include at least one inorganic film TFE1 or TFE2 in order to prevent or reduce oxygen and/or moisture from permeating into the display element layer EML. For example, in one or more embodiments, the encapsulation layer TFE may include a first encapsulation inorganic film TFE1 and a second encapsulation inorganic film TFE2.

The first encapsulation inorganic film TFE1 may be arranged on the second electrode CAT. The first encapsulation inorganic film TFE1 may be formed as multiple films in which one or more inorganic films selected from among a silicon nitride (SiNₓ) layer, a silicon oxynitride (SiON) layer, and a silicon oxide (SiOₓ) layer are alternately stacked. The first encapsulation inorganic film TFE1 may be formed by a chemical vapor deposition (CVD) process.

The second encapsulation inorganic film TFE2 may be arranged on the first encapsulation inorganic film TFE1. The second encapsulation inorganic film TFE2 may be formed as a titanium oxide (TiOₓ) layer or an aluminum oxide (AlOₓ) layer, but embodiments of the present disclosure are not limited thereto. The second encapsulation inorganic film TFE2 may be formed by an atomic layer deposition (ALD) process. A thickness of the second encapsulation inorganic film TFE2 may be smaller (less) than a thickness of the first encapsulation inorganic film TFE1.

An organic film APL may be arranged on the encapsulation layer TFE and may be a layer for increasing interfacial adhesive strength between the encapsulation layer TFE and the optical layer OPL. The organic film APL may be an organic film made of an acrylic resin, an epoxy resin, a phenolic resin, a polyamide resin, a polyimide resin, and/or the like.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be arranged on the organic film APL.

The first color filter CF1 may overlap the first emission area EA1 of the first pixel PX1. The first color filter CF1 may be to transmit the light of the first color, for example, the light of the blue wavelength band, therethrough. The blue wavelength band may be approximately (about) 370 nm to about 460 nm. Therefore, the first color filter CF1 may be to transmit the light of the first color among light emitted from the first emission area EA1 therethrough.

The second color filter CF2 may overlap the second emission area EA2 of the second pixel PX2. The second color filter CF2 may be to transmit the light of the second color, for example, the light of the green wavelength band, therethrough. The green wavelength band may be approximately (about) 480 nm to about 560 nm. Therefore, the second color filter CF2 may be to transmit the light of the second color among light emitted from the second emission area EA2 therethrough.

The third color filter CF3 may overlap the third emission area EA3 of the third pixel PX3. The third color filter CF3 may be to transmit the light of the third color, for example, the light of the red wavelength band, therethrough. The red wavelength band may be approximately (about) 600 nm to about 750 nm. Therefore, the third color filter CF3 may be to transmit the light of the third color among light emitted from the third emission area EA3 therethrough.

Each of the plurality of lenses LNS may be arranged on each of the first color filter CF1, the second color filter CF2, and the third color filter CF3. Each of the plurality of lenses LNS may be a structure for increasing a ratio of light directed to a front surface of the display device 10. Each of the plurality of lenses LNS may have a cross-sectional shape convex in an upward direction.

The filling layer FIL may be arranged on the plurality of lenses LNS. The filling layer FIL may have a set or predetermined refractive index so that light travels in the third direction DR3 at an interface between the plurality of lenses LNS and the filling layer FIL. In addition, the filling layer FIL may also be a planarizing layer. The filling layer FIL may be an organic film made of an acrylic resin, an epoxy resin, a phenolic resin, a polyamide resin, a polyimide resin, and/or the like.

The cover layer CVL may be arranged on the filling layer FIL. The cover layer CVL may be a glass substrate or a polymer resin such as a resin. In one or more embodiments, the cover layer CVL is the glass substrate, the cover layer CVL may be attached onto the filling layer FIL. In these embodiments, the filling layer FIL may serve to adhere the cover layer CVL. When the cover layer CVL is the glass substrate, the cover layer CVL may serve as an encapsulation substrate. In one or more embodiments, the cover layer CVL is the polymer resin such as the resin, the cover layer CVL may be directly applied onto the filling layer FIL.

The polarizing plate POL may be arranged on a (e.g., one) surface of the cover layer CVL. The polarizing plate POL may be a structure for reducing or preventing visibility degradation caused by reflection of external light. The polarizing plate POL may include a linear polarizing plate and a phase retardation film. For example, in one or more embodiments, the phase retardation film may be a λ/4 plate (quarter-wave plate), but embodiments of the present disclosure are not limited thereto. However, in embodiments in which the visibility degradation caused by reflection of external light is sufficiently improved by the first to third color filters CF1, CF2, and CF3, the polarizing plate POL may not be provided.

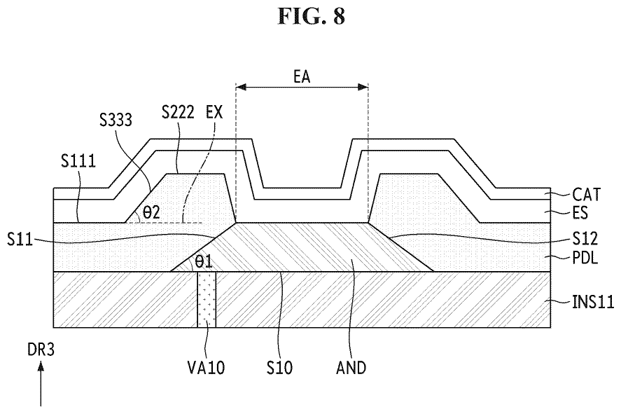

FIG. 8 is a cross-sectional view of a display device 10 according to one or more embodiments of the present disclosure. For example, FIG. 8 may be a cross-sectional view in respect to the periphery of the first electrode AND of FIG. 7.

The display device 10 of FIG. 8 is different from the display device 10 of FIG. 7 described above in a taper angle, and the following description will focus on the difference.

As illustrated in FIG. 8, a taper angle θ1 of a first electrode AND may have an even angle (e.g., acute angle). For example, the taper angle θ1 of the first electrode AND may be smaller (less) than or equal to (e.g., the same as) about 45 degrees. Here, the taper angle θ1 of the first electrode AND may be an angle between a lower surface S10 and a first side surface S11 of the first electrode AND. The lower surface S10 of the first electrode AND may refer to a (e.g., one) surface of the first electrode AND adjacent to (e.g., facing) (or in contact with) the eleventh insulating film INS11. The first side surface S11 of the first electrode AND may refer to a (e.g., one) surface of the first electrode AND adjacent to (e.g., facing) (or in contact with) the pixel defining film PDL. For example, the taper angle θ1 of the first electrode may be an acute angle. For example, the taper angle θ1 of the first electrode may be less than or equal to about 45 degrees. The taper angle θ1 is the angle between the lower surface S10 and the first side surface S11 of the first electrode. The lower surface S10 of the first electrode refers to the surface of the first electrode that is adjacent to or in contact with the eleventh insulating film INS11. The first side surface S11 of the first electrode refers to the surface of the first electrode that is adjacent to or in contact with the pixel defining film PDL.

According to one or more embodiments, a taper angle between the lower surface S10 of the first electrode AND and a second side surface S12 of the first electrode AND may be the same as the taper angle θ1 between the lower surface S10 and the first side surface S11 of the first electrode AND described above. The second side surface S12 of the first electrode AND may be at the opposite side of the first side surface S11 described above and may refer to a (e.g., one) surface of the first electrode AND adjacent to (e.g., facing) (or in contact with) the pixel defining film PDL.

The pixel defining film PDL may include a first surface S111 and a second surface S222 located at different heights, and the second surface S222 may be positioned to be higher than the first surface S111. For example, based on an upper surface of the eleventh insulating film INS11 (e.g., one surface of the eleventh insulating film INS11 opposite to (e.g., facing or adjacent to) the lower surface S10 of the first electrode AND), the second surface S222 may be arranged to be higher than the first surface S111. For example, the pixel defining film PDL may have a first surface S111 and a second surface S222 at different heights, with the second surface S222 positioned higher than the first surface S111. For example, relative to the upper surface of the eleventh insulating film INS11 (which faces or is adjacent to the lower surface S10 of the first electrode AND), the second surface S222 is positioned higher than the first surface S111.

The first surface S111 of the pixel defining film PDL may overlap the eleventh insulating film INS11, and the second surface S222 of the pixel defining film PDL may overlap the eleventh insulating film INS11 and the first electrode AND. A third surface S333 of the pixel defining film PDL may be arranged between the first surface S111 and the second surface S222. The first surface S111 and the second surface S222 of the pixel defining film PDL may be connected to each other by the third surface S333 of the pixel defining film PDL.

Because the taper angle θ1 of the first electrode AND is small, a step difference of the pixel defining film PDL on the first electrode AND may be reduced, and a step coverage of the pixel defining film PDL on the first electrode AND may be increased. In the present context, step coverage refers to the ability of the pixel defining film PDL to uniformly cover the surface features of the first electrode, ensuring consistent thickness and reducing defects. For example, in one or more embodiments, a height difference between the first surface S111 and the second surface S222 of the pixel defining film PDL may be reduced. Accordingly, an angle θ2 (e.g., taper angle of the pixel defining film) between an extension surface EX of the first surface S111 and the third surface S333 of the pixel defining film PDL may have a gentle size of acute angle. For example, because the taper angle θ1 of the first electrode is small, the step difference of the pixel defining film PDL on the first electrode may be reduced, and the step coverage of the pixel defining film PDL on the first electrode may be improved. In some embodiments, the height difference between the first surface S111 and the second surface S222 of the PDL may be reduced or minimized. Consequently, the angle θ2 between an extension surface EX of the first surface S111 and the third surface S333 of the pixel defining film PDL may form an acute angle, which is a small, less sharp angle that facilitates smoother transitions between surfaces.

As described above, because the step difference of the pixel defining film PDL is reduced, a disconnection of the second electrode CAT which is arranged on the pixel defining film PDL to overlap a step area of the pixel defining film PDL may be prevented or reduced. Because the second electrode CAT has a significantly small thickness, it may easily be disconnected if (e.g., when) the step difference of the pixel defining film PDL is large. However, according to the display device 10 of one or more embodiments of the present disclosure, because the step difference of the pixel defining film PDL is small and gentle, a disconnection of the second electrode CAT may be prevented or reduced.

In one or more embodiments, the light emitting stack ES of FIG. 8 may be arranged between the pixel defining film PDL and the second electrode CAT. The light emitting stack ES of FIG. 8 may have the same structure as the light emitting stack ES of FIG. 7 described above. For example, in one or more embodiments, the light emitting stack ES of FIG. 8 may include a first stack layer IL1, a second stack layer IL2, and a third stack layer IL3.

The pixel defining film PDL of FIG. 8 may have substantially the same structure as the pixel defining film PDL of FIG. 7 described above. For example, the pixel defining film PDL in FIG. 8 may include a first pixel defining film PDL1, a second pixel defining film PDL2, and a third pixel defining film PDL3.

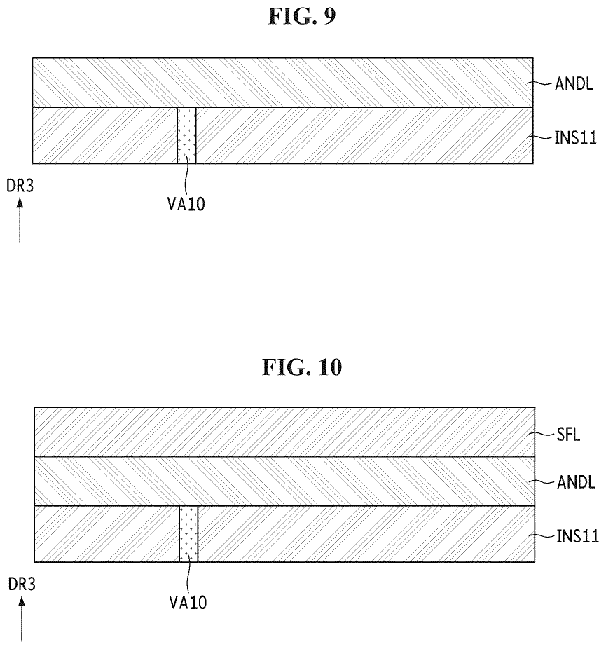

FIGS. 9 to 20 are cross-sectional views for explaining processes of a method of manufacturing a display device 10 according to one or more embodiments of the present disclosure.

First, as illustrated in FIG. 9, a first electrode layer ANDL may be placed on the eleventh insulating film INS11. For example, the first electrode layer ANDL may be arranged on the entire surface of the eleventh insulating film INS11. The first electrode layer ANDL may be made of a material containing metal. For example, in one or more embodiments, the first electrode layer ANDL may be formed of any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one of them. The first electrode layer ANDL may be connected to the tenth via VA10.

Subsequently, as illustrated in FIG. 10, a sacrificial layer SFL may be placed on the first electrode layer ANDL. For example, the sacrificial layer SFL may be arranged on the entire surface of the first electrode layer ANDL. The sacrificial layer SFL may be formed of a material including an inorganic film. For example, in one or more embodiments, the sacrificial layer SFL may be formed of a material including a silicon-oxide film (SiOₓ).

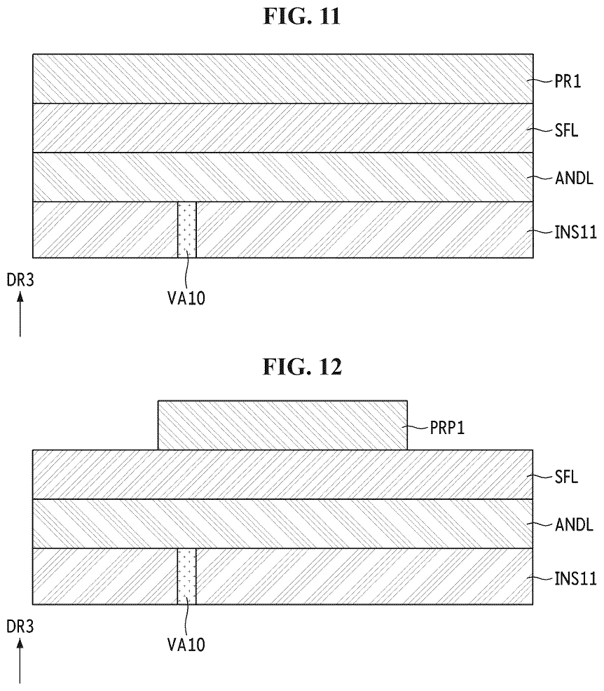

Next, as illustrated in FIG. 11, a first photoresist PR1 may be placed on the sacrificial layer SFL. For example, the first photoresist PR1 may be arranged on the entire surface of a substrate (e.g., substrate SSUB) including the sacrificial layer SFL.

Thereafter, as illustrated in FIG. 12, as the first photoresist PR1 is selectively removed through a light exposure process using a mask and a developing process, a first photoresist pattern PRP1 may be formed on the sacrificial layer SFL.

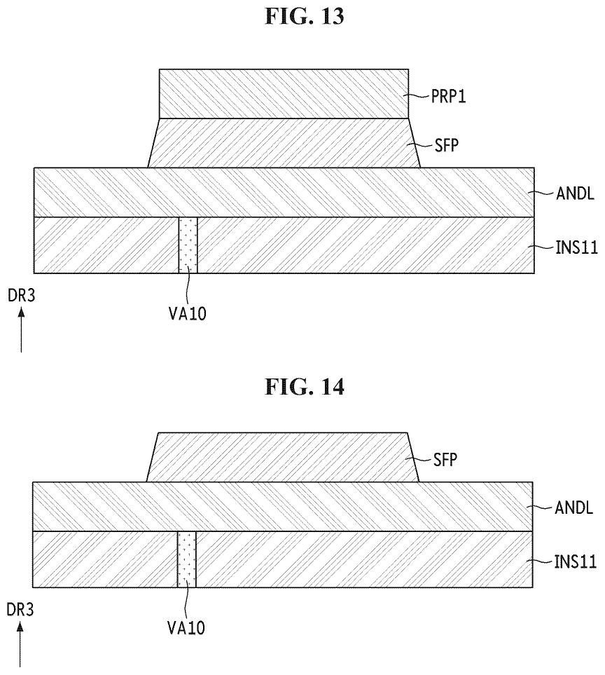

Subsequently, as illustrated in FIG. 13, as the sacrificial layer SFL is selectively removed by using the first photoresist pattern PRP1 as a mask, a sacrificial pattern layer SFP may be formed on the first electrode layer ANDL. For example, the sacrificial pattern layer SFP may be arranged between the first electrode layer ANDL and the first photoresist pattern PRP1.

Next, as illustrated in FIG. 14, the first photoresist pattern PRP1 may be removed. Accordingly, the sacrificial pattern layer SFP may be exposed to the outside.

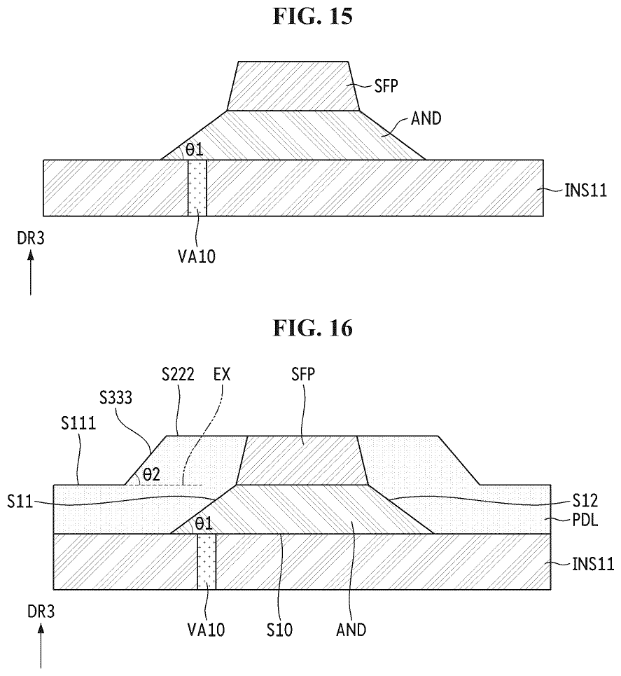

Subsequently, as illustrated in FIG. 15, as the first electrode layer ANDL is selectively removed by using the sacrificial pattern layer SFP as a mask (e.g., hard mask), a first electrode AND may be formed on the eleventh insulating film INS11. The first electrode layer ANDL may be selectively removed through a dry-etching or wet-etching method. For example, in one or more embodiments, the first electrode layer ANDL may be selectively removed through dry-etching. In this regard, because an etch rate of the first electrode layer ANDL is high, the sacrificial pattern layer SFP may be maintained in a nearly unetched state while the first electrode layer ANDL is etched. If (e.g., when) the first electrode layer ANDL is being etched for a long time at low etching intensity, the first electrode AND formed as described above may have an even taper angle θ1. The sacrificial pattern layer SFP may be maintained without being removed during a longer etching process time than a photoresist (e.g., photoresist PR1). This is because the sacrificial pattern layer SFP contains the silicon oxide film. Accordingly, if (e.g., when) the first electrode layer ANDL is etched using the sacrificial pattern layer SFP as a mask, a taper angle θ1 of the first electrode AND may be formed to be even.

Next, as illustrated in FIG. 16, a pixel defining film PDL may be placed on the first electrode AND and the eleventh insulating film INS11. At this time, the pixel defining film PDL may not be formed on the sacrificial pattern layer SFP and be formed along the periphery of the sacrificial pattern layer SFP. For example, in a plan view, the pixel defining film PDL may have a shape around (e.g., surrounding) the sacrificial pattern layer SFP. And the pixel defining film PDL and a side surface of the sacrificial pattern layer SFP may be in contact. In one or more embodiments, when the pixel defining film PDL and sacrificial pattern layer SFP are formed of the same material, the pixel defining film PDL and sacrificial pattern layer SFP in FIG. 16 may be formed integrally without an interface therebetween.

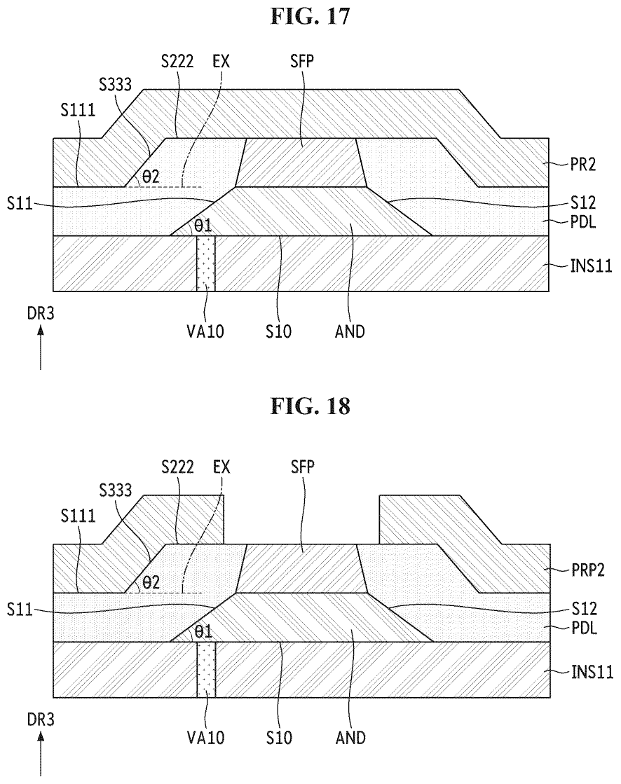

Subsequently, as illustrated in FIG. 17, a second photoresist PR2 may be placed on the pixel defining film PDL and the sacrificial pattern layer SFP. For example, the second photoresist PR2 may be arranged on the entire surface of the substrate SSUB including the pixel defining film PDL and the sacrificial pattern layer SFP.

Next, as illustrated in FIG. 18, as the second photoresist PR2 is selectively removed through a light exposure process using a mask and a developing process, a second photoresist pattern PRP2 may be formed on the pixel defining film PDL.

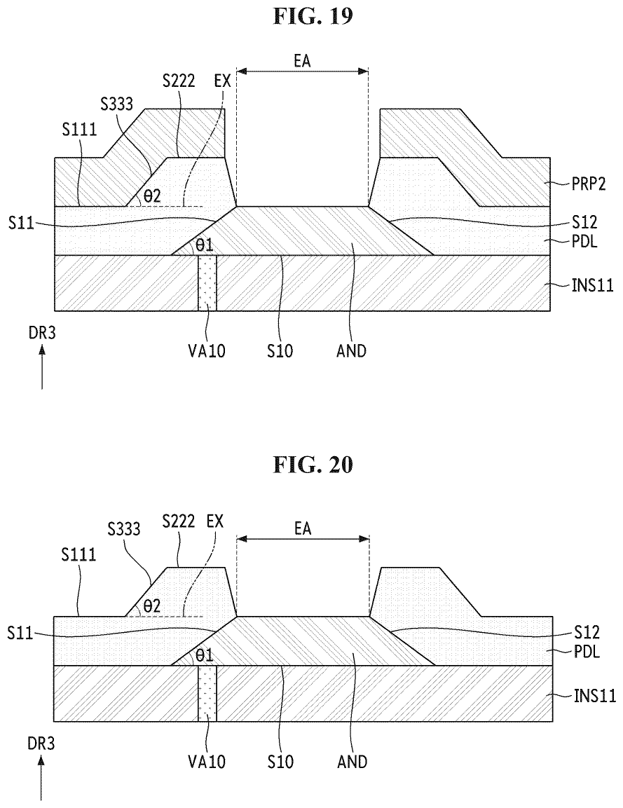

Subsequently, as illustrated in FIG. 19, as the sacrificial pattern layer SFP is removed using the second photoresist patter PRP2 as a mask, an emission area EA may be formed. For example, a pixel defining film PDL defining the emission area EA may be formed on the first electrode AND.

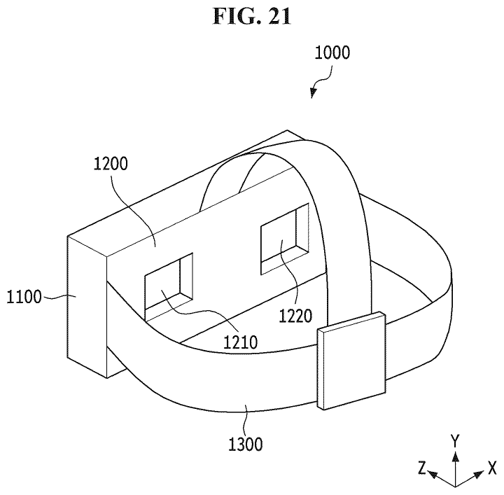

Next, as illustrated in FIG. 20, the second photoresist pattern PRP2 may be removed. Accordingly, the pixel defining film PDL may be exposed to the outside.

Subsequently, as illustrated in FIG. 8, a light emitting stack ES may be placed on the pixel defining film PDL and the first electrode AND, and thereafter, a second electrode CAT may be placed on the light emitting stack ES.

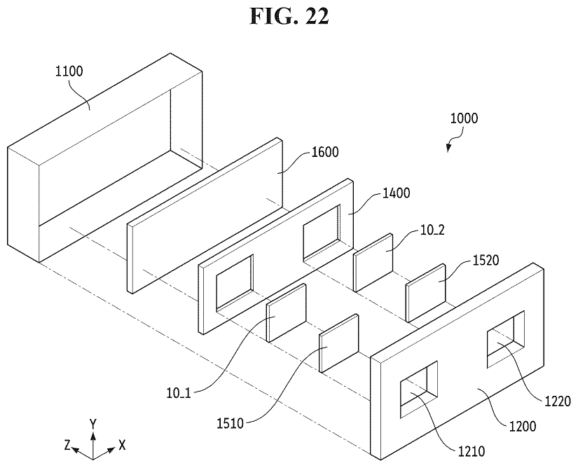

FIG. 21 is a perspective view illustrating a head mounted display device according to one or more embodiments of the present disclosure. FIG. 22 is an exploded perspective view illustrating an example of the head mounted display device of FIG. 21.

Referring to FIG. 21 and FIG. 22, a head mounted display device 1000 according to one or more embodiments includes a first display device 10_1, a second display device 10_2, a display device housing part 1100, a housing part cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to a user's left eye, and the second display device 10_2 provides an image to a user's right eye. Each of the first display device 10_1 and the second display device 10_2 is substantially the same as the display device 10 described with reference to FIG. 1 and FIG. 2, and a description of the first display device 10_1 and the second display device 10_2 is thus not provided for conciseness.

The first optical member 1510 may be arranged between the first display device 10_1 and the first eyepiece 1210. The second optical member 1520 may be arranged between the second display device 10_2 and the second eyepiece 1220. Each of the first optical member 1510 and the second optical member 1520 may include at least one convex lens.

The middle frame 1400 may be arranged between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be arranged between the middle frame 1400 and the display device housing part 1100. The control circuit board 1600 may be connected to the first display device 10_1 and the second display device 10_2 through a connector. The control circuit board 1600 may convert an image source input from the outside into digital video data DATA, and transmit the digital video data DATA to the first display device 10_1 and the second display device 10_2 through the connector.

In one or more embodiments, the control circuit board 1600 may be to transmit the digital video data DATA corresponding to a left eye image, improved or optimized for the user's left eye, to the first display device 10_1, and transmit the digital video data DATA corresponding to a right eye image, improved or optimized for the user's right eye, to the second display device 10_2. In one or more embodiments, the control circuit board 1600 may be to transmit the same digital video data DATA to the first display device 10_1 and the second display device 10_2.

The display device housing part 1100 serves to house the first display device 10_1, the second display device 10_2, the middle frame 1400, the first optical member 1510, the second optical member 1520, and the control circuit board 1600. The housing part cover 1200 is arranged to cover opened one surface of the display device housing part 1100. The housing part cover 1200 may include the first eyepiece 1210 at which the user's left eye looks and the second eyepiece 1220 at which the user's right eye looks. It has been illustrated in FIG. 21 and FIG. 22 that the first eyepiece 1210 and the second eyepiece 1220 are separately arranged, but embodiments of the present disclosure are not limited thereto. In one or more embodiments, the first eyepiece 1210 and the second eyepiece 1220 may be merged as one eyepiece (e.g., integrated into a single piece). For example, the display device housing part 1100 contains the first and second display devices 10_1 and 10_2, the middle frame 1400, the first and second optical members 1510 and 1520, and the control circuit board 1600. The housing part cover 1200 is designed to cover one open surface of the housing part 1100. It includes the first eyepiece 1210 for the user's left eye and the second eyepiece 1220 for the user's right eye. While FIG. 21 and FIG. 22 show the eyepieces separately, they can also be integrated into a single eyepiece in some embodiments.

The first eyepiece 1210 may be aligned with the first display device 10_1 and the first optical member 1510, and the second eyepiece 1220 may be aligned with the second display device 10_2 and the second optical member 1520. Accordingly, a user may view an image of the first display device 10_1 magnified as a virtual image by the first optical member 1510 through the first eyepiece 1210, and may view an image of the second display device 10_2 magnified as a virtual image by the second optical member 1520 through the second eyepiece 1220.

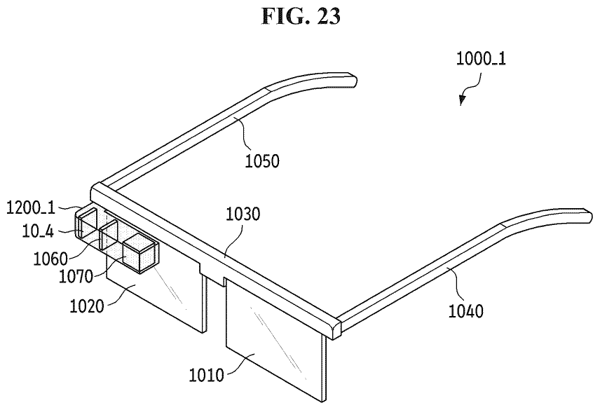

The head mounted band 1300 serves to fix the display device housing part 1100 to a user's head so that the first eyepiece 1210 and the second eyepiece 1220 of the housing part cover 1200 may be maintained in a state in which they are aligned with the user's left eye and right eye, respectively. In one or more embodiments, when the display device housing part 1200 is implemented to have a light weight and a small size, the head mounted display device 1000 may include an eyeglass frame as illustrated in FIG. 23 instead of the head mounted band 1300.

In one or more embodiments, the head mounted display device 1000 may further include a battery for supplying power, an external memory slot for housing an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a wireless fidelity (WiFi) module, or a Bluetooth module.

FIG. 23 is a perspective view illustrating a head mounted display device according to one or more embodiments of the present disclosure.

Referring to FIG. 23, a head mounted display device 1000_1 according to one or more embodiments may be a glasses-type (kind) display device in which a display device housing part 1200_1 is implemented to have a light weight and a small size. The head mounted display device 1000_1 according to one or more embodiments may include a display device 10_4, a left eye lens 1010, a right eye lens 1020, a support frame 1030, glasses frame legs 1040 and 1050, an optical member 1600, an optical path changing member 1070, and the display device housing part 1200_1.

The display device housing part 1200_1 may include the display device 10_4, the optical member 1600, and the optical path changing member 1070. An image displayed on the display device 10_4 may be magnified by the optical member 1600, changed in an optical path by the optical path changing member 1070, and provided to a user's right eye through the right eye lens 1020. As a result, a user may view an augmented reality image in which a virtual image displayed on the display device 10_4 and a real image seen through the right eye lens 1020 are combined, through his/her right eye.

It has been illustrated in FIG. 23 that the display device housing part 1200_1 is arranged at a right end of the support frame 1030, but embodiments of the present disclosure are not limited thereto. For example, in one or more embodiments, the display device housing part 1200_1 may be arranged at a left end of the support frame 1030, and in these embodiments, an image of the display device 10_4 may be provided to a user's left eye. In one or more embodiments, the display device housing parts 1200_1 may be arranged at both (e.g., simultaneously) the left and right ends of the support frame 1030, and in these embodiments, the user may view an image displayed on the display device 10_4 through both (e.g., simultaneously) his/her left and right eyes.

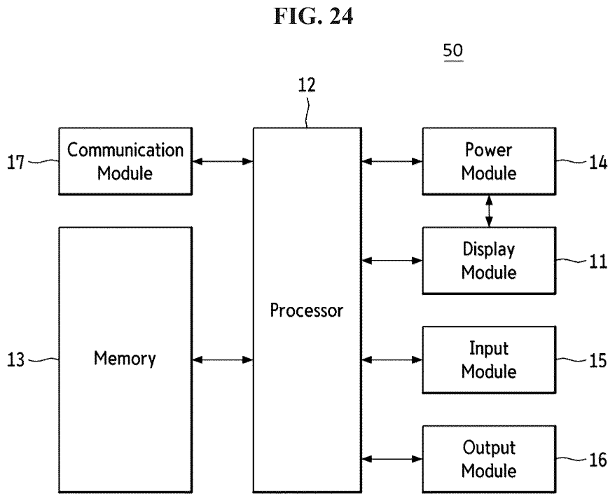

FIG. 24 is a block diagram of an electronic device according to one or more embodiments of the present disclosure. Referring to FIG. 24, an electronic device 50 according to one or more embodiments may include a display module 11 (e.g., display device 10), a processor 12, a memory 13, and a power module 14. In one or more embodiments, the electronic device 50 may further include an input module 15, an output module 16 (e.g., a non-image output module), and/or a communication module 17.

The electronic device 50 may output one or more suitable information in the form of images through the display module 11. When the processor 12 executes an application stored in the memory 13, image information provided by the application may be provided to a user through the display module 11. The power module 14 may include a power supply module such as a power adapter or a battery device, and a power conversion module that converts the power supplied by the power supply module to generate power desired or required for the operation of the electronic device 50. The input module 15 may provide input information to the processor 12 and/or the display module 11. The output module 16 may receive/output information other than images transmitted from the processor 12, such as sound, haptics, and light, and provide the information to the user. The communication module 17 is a module that is responsible for transmitting and receiving information between the electronic device 50 and an external device, and may include a receiving unit and a transmitting unit.

For example, the electronic device 50, as illustrated in FIG. 24, includes a display module 11, a processor 12, a memory 13, and a power module 14. It may also feature an input module 15, an output module 16, and a communication module 17. The device can display images via the display module 11, with the processor 12 executing applications stored in the memory 13 to provide image information to the user. The power module 14 supplies and converts power for the device's operation.

The input module 15 provides input information, while the output module 16 handles non-image outputs like sound and haptics. The communication module 17 manages data transmission between the device and external devices.

At least one of the components of the electronic device 50 described above may be included in the display device according to one or more embodiments described above. In one or more embodiments, some of the individual modules functionally included in one module may be included in the display device, and others may be provided separately from the display device. For example, in one or more embodiments, the display device includes a display module 11, and the processor 12, memory 13, and power module 14 may be provided in the form of other devices within the electronic device 50 other than the display device.

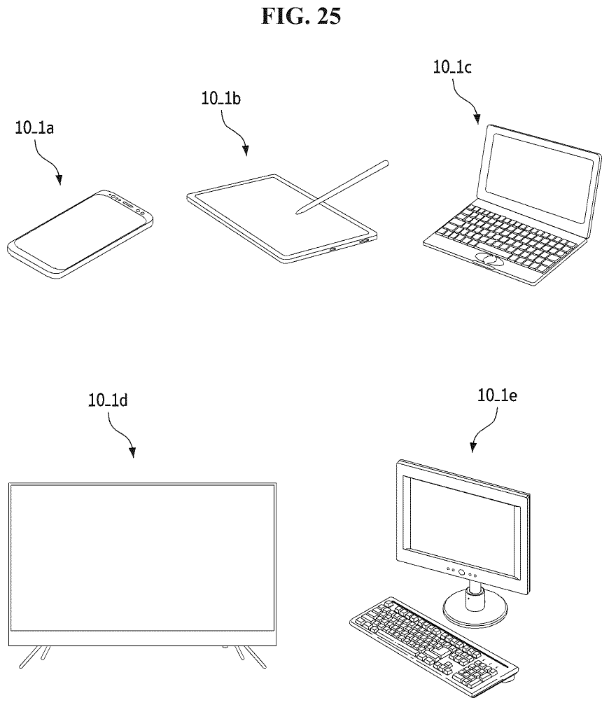

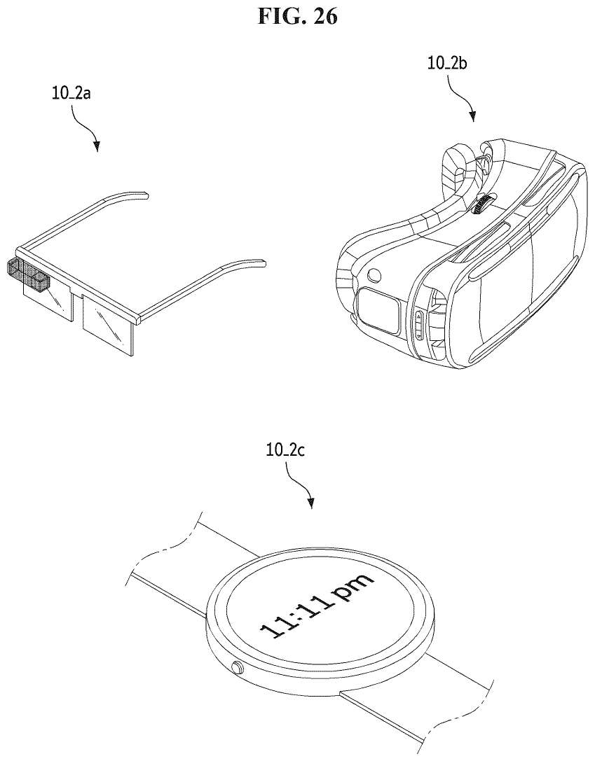

FIGS. 25, 26, and 27 are schematic diagram illustrating electronic devices according to embodiments of the present disclosure. FIGS. 25 to 27 illustrate examples of suitable electronic devices to which the display device according to one or more embodiments is applied.

FIG. 25 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the cases of tablet PCs 10_1b, laptops 10_1c, TVs 10_1d, and desk monitors 10_1e, they also include display modules and input modules similar to smartphones 10_1, and may additionally include communication modules in some cases.

FIG. 26 shows examples of an electronic device including a display module being applied to a wearable electronic device. The wearable electronic device may be a smart glasses 10_2a, a head-mounted display 10_2b, a smart watch 10_2c, and/or the like.

The smart glasses 10_2a and the head-mounted display 10_2b may each include a display module that emits a display image and a reflector that reflects the emitted display image and provides it to the user's eyes, thereby providing a virtual reality or augmented reality image to the user.

The smart watch 10_2c includes a biometric sensor as an input device, and may provide biometric information recognized by the biometric sensor to the user through the display module.

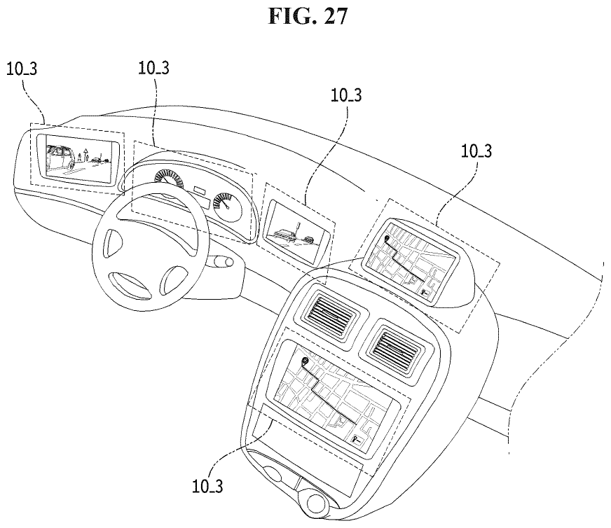

FIG. 27 illustrates an embodiment in which an electronic device including a display module is applied to a vehicle. For example, the electronic device 10_3 may be applied to a dashboard, center fascia, and/or the like of a vehicle, or may be applied to a CID (Center Information Display) placed on a dashboard of a vehicle, or a room mirror display replacing a side mirror.

In the present disclosure, it will be understood that the terms “comprise(s)/comprising,” “include(s)/including,” or “have/has/having” specify the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

In the context of the present application and unless otherwise defined, the terms “use,” “using,” and “used” may be considered synonymous with the terms “utilize,”“utilizing,”and “utilized,”respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

The light emitting element, the display module, the display device, the electronic device/apparatus, the device-manufacturing apparatus, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with one another, partially or entirely, and may be technically interlocked and operated in various suitable ways, and each embodiment may be implemented independently of one another or in conjunction with one another in any suitable manner unless otherwise stated or implied.

In concluding the detailed description, those skilled in the art will appreciate that many variations and modifications can be made to the described embodiments without substantially departing from the principles of disclosure. Therefore, the disclosed embodiments of present disclosure are used in a generic and descriptive sense only and not for purposes of limitation. It is further understood that the scope of the present disclosure is defined by the appended claims and equivalents thereof rather than the detailed description described above, and all modifications and alterations derived from the claims and their equivalents fall within the scope of the present disclosure.

What is claimed is:

1. A display device comprising:
a substrate;
a first electrode on the substrate;
a pixel defining film on the first electrode and defining an emission area;
a light emitting stack on the first electrode; and
a second electrode on the light emitting stack and the pixel defining film,
wherein a taper angle of the first electrode is less than or equal to about 45 degrees.

2. The display device of claim 1,
wherein the taper angle of the first electrode is an angle between a lower surface of the first electrode and a side surface of the first electrode.

3. The display device of claim 2,
further comprising an insulating film between the substrate and the first electrode.

4. The display device of claim 3,
wherein the lower surface of the first electrode comprises a surface of the first electrode adjacent to the insulating film.

5. The display device of claim 3,
wherein the side surface of the first electrode comprises a surface of the first electrode adjacent to the pixel defining film.

6. The display device of claim 3,
wherein the pixel defining film comprises a first surface and a second surface located at different heights.

7. The display device of claim 6,
the second surface of the pixel defining film is positioned to be higher than the first surface of the pixel defining film.

8. The display device of claim 7,
wherein, based on an upper surface of the insulating film, the second surface of the pixel defining film is positioned to be higher than the first surface of the pixel defining film.

9. An optical device comprising:
a display device; and
an optical path changing member on the display device,
wherein the display device comprises:
a substrate;
a first electrode on the substrate;
a pixel defining film on the first electrode and defining an emission area;
a light emitting stack on the first electrode; and
a second electrode on the light emitting stack and the pixel defining film, and
wherein a taper angle of the first electrode is less than or equal to about 45 degrees.

10. The optical device of claim 9,
wherein a taper angle of the first electrode is an angle between a lower surface of the first electrode and a side surface of the first electrode.

11. The optical device of claim 10,
further comprising an insulating film between the substrate and the first electrode.

12. The optical device of claim 11,
wherein the lower surface of the first electrode comprises a surface of the first electrode adjacent to the insulating film.

13. The optical device of claim 11,
wherein the side surface of the first electrode comprises a surface of the first electrode adjacent to the pixel defining film.

14. The optical device of claim 11,
wherein the pixel defining film comprises a first surface and a second surface located at different heights.

15. The optical device of claim 14,
wherein the second surface of the pixel defining film is positioned to be higher than the first surface of the pixel defining film.

16. The optical device of claim 15,
wherein, based on an upper surface of the insulating film, the second surface of the pixel defining film is positioned to be higher than the first surface of the pixel defining film.

17. An electronic device comprising:
a display device comprising a screen,
wherein the display device comprises:
a substrate;
a first electrode on the substrate;
a pixel defining film on the first electrode and defining an emission area;
a light emitting stack on the first electrode; and
a second electrode on the light emitting stack and the pixel defining film,
wherein a taper angle of the first electrode is less than or equal to about 45 degrees.

18. The electronic device of claim 17,
wherein the taper angle of the first electrode is an angle between a lower surface of the first electrode and a side surface of the first electrode.

19. The electronic device of claim 18,
further comprising an insulating film between the substrate and the first electrode.

20. The electronic device of claim 17,
wherein the electronic device includes VR devices, mobile phones, video phones, smart pads, smart watches, tablet PCs, vehicle displays, monitors, laptops, head mounted displays, and automobiles.
